(19) United States
(12) Patent Application Publication
(10) Pub. No.: US 2026/0143921 A1
(43) Pub. Date: May 21, 2026

(54) DISPLAY PANEL, ELECTRONIC APPARATUS INCLUDING THE SAME, AND METHOD OF MANUFACTURING DISPLAY PANEL

(71) Applicant: Samsung Display Co., Ltd., Yongin-si (KR)

(72) Inventor: Hyuneok SHIN, Yongin-si (KR)

(73) Assignee: Samsung Display Co., Ltd., Yongin-si (KR)

(21) Appl. No.: 19/388,037

(22) Filed: Nov. 13, 2025

(30) Foreign Application Priority Data
Nov. 18, 2024 (KR) 10-2024-0164247

(51) Int. Cl. H10K 59/122; H10K 59/12; H10K 59/80; H10K 85/60; H10K 102/10

(52) U.S. Cl. CPC H10K 59/122; H10K 59/1201; H10K 59/80523; H10K 59/80524; H10K 59/873; H10K 85/626; H10K 85/633; H10K 85/654; H10K 85/6572; H10K 2102/102; H10K 2102/103

(57) ABSTRACT

Provided is a display panel including a base layer in which a plurality of pixel regions and a non-pixel region surrounding the pixel regions are defined, a pixel-defining film on the base layer, at least partially overlapping the non-pixel region, and in which a valley pattern depressed from an upper surface along a thickness direction is defined, a plurality of light-emitting elements on the base layer, and in which a depression pattern corresponding to the valley pattern is defined, and an organic layer composed of a first material and at least partially filling at least a portion of the depression pattern. A glass transition temperature of the first material is 50° C. to 90° C.

### CROSS-REFERENCE TO RELATED APPLICATIONS

This U.S. non-provisional patent application claims priority under 35 U.S.C. § 119 of Korean Patent Application No. 10-2024-0164247, filed on Nov. 18, 2024, the entire contents of which are hereby incorporated by reference.

### BACKGROUND

Some example embodiments relate to a display panel, an electronic apparatus including the same, and/or a method of manufacturing a display panel, and more particularly, to a display panel in which luminance is improved and color mixture is prevented, an electronic apparatus including the same, and/or a method of manufacturing a display panel.

Electronic apparatuses, such as smartphones, tablet PCs, digital cameras, laptop computers, car navigation systems, and televisions, may provide an image to a user and include a display panel for displaying an image.

A display panel may be formed by dividing pixels into red, green, and blue pixels for displaying colors, and a light-emitting layer for the color of each corresponding pixel may be formed separately into each pixel. In general, the light-emitting layer has been formed by using a deposition method using a shadow mask (e.g., a shadow photomask such as a negative photomask). However, since a defect such as the mask's sagging may occur, a process has been developed to form a light-emitting layer and other organic layers across the respective pixels in common through an open mask (e.g., an open photomask such as a positive photomask).

However, when an organic layer is formed in common, a lateral leakage current between adjacent pixels may occur due to the organic layer provided in common, thereby causing a luminance defect and color mixture between the adjacent pixels.

### SUMMARY

Some example embodiments may provide a display panel in which color mixture between adjacent pixels is prevented or reduced in likelihood of occurrence and/or in impact from occurrence, luminance degradation is prevented or reduced in likelihood of occurrence and/or in impact from occurrence, and simultaneously element-driving reliability is improved by preventing or reducing the likelihood of occurrence of a lateral leakage current between the adjacent pixels, an electronic apparatus including the same, and/or a method of manufacturing a display panel.

According to some example embodiments, a display panel includes a base layer in which a plurality of pixel regions and a non-pixel region surrounding the pixel regions are defined, a pixel-defining film on the base layer, at least partially overlapping the non-pixel region, and in which a valley pattern depressed from an upper surface along a thickness direction is defined, a plurality of light-emitting elements on the base layer, and in which a depression pattern corresponding to the valley pattern is defined, and an organic layer including a first material and at least partly filling a portion of the depression pattern. A glass transition temperature of the first material is 50° C. to 90° C.

According to some example embodiments, the valley pattern may at least partly surround at least a portion of each of the plurality of pixel regions.

According to some example embodiments, the first material may include at least one of compounds in Compound Group 1 below:

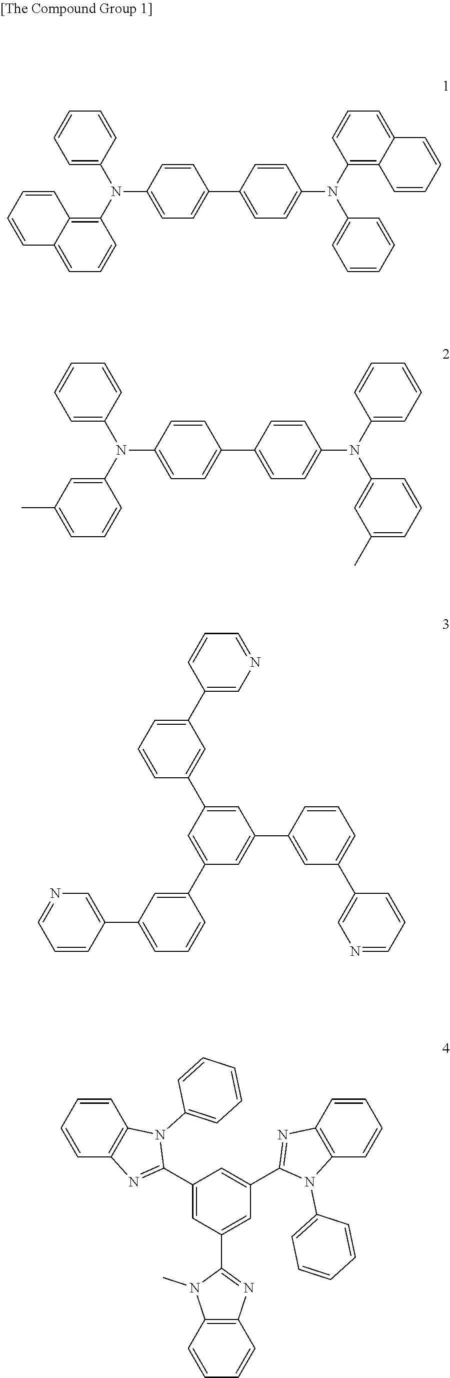 [SMILES: c1ccc(N(c2ccc(-c3ccc(N(c4ccccc4)c4cccc5ccccc45)cc3)cc2)c2cccc3ccccc23)cc1 ; Cc1cccc(N(c2ccccc2)c2ccc(-c3ccc(N(c4ccccc4)c4cccc(C)c4)cc3)cc2)c1 ; c1cncc(-c2cccc(-c3cc(-c4cccc(-c5cccnc5)c4)cc(-c4cccc(-c5cccnc5)c4)c3)c2)c1 ; Cn1c(-c2cc(-c3nc4ccccc4n3-c3ccccc3)cc(-c3nc4ccccc4n3-c3ccccc3)c2)nc2ccccc21]

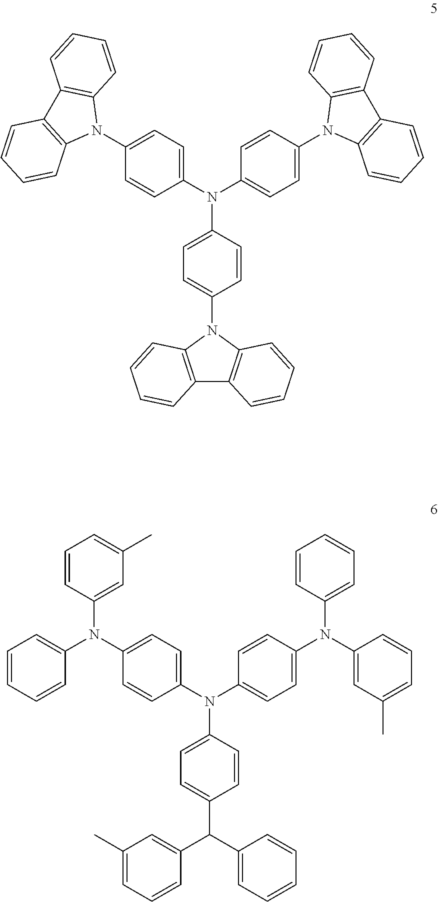 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; Cc1cccc(C(c2ccccc2)c2ccc(N(c3ccc(N(c4ccccc4)c4cccc(C)c4)cc3)c3ccc(N(c4ccccc4)c4cccc(C)c4)cc3)cc2)c1]

According to some example embodiments, the plurality of light-emitting elements may each include a first electrode, a functional layer on the first electrode, and a second electrode on the functional layer, and the pixel-defining film may define a pixel opening which exposes a portion of an upper surface of the first electrode and corresponds to each of the plurality of pixel regions.

According to some example embodiments, the second electrode may include a first layer on the functional layer, and a second layer on the first layer, and the organic layer may be between the first layer and the second layer.

According to some example embodiments, at least a portion of the first layer may be electrically disconnected in the non-pixel region.

According to some example embodiments, the first layer may include a (1-1)-th layer on the functional layer and containing silver (Ag), and a (1-2)-th layer disposed on the (1-1)-th layer and containing at least one among indium tin oxide (ITO), indium zinc oxide (IZO), zinc oxide (ZnO), and indium tin zinc oxide (ITZO).

According to some example embodiments, the second layer may include at least one among indium tin oxide (ITO), indium zinc oxide (IZO), zinc oxide (ZnO), and indium tin zinc oxide (ITZO).

According to some example embodiments, the second layer may include a first portion overlapping the plurality of pixel regions and a second portion overlapping the non-pixel region, and the first portion may be directly disposed on the first layer.

According to some example embodiments, at least a portion of the second portion may be directly disposed on the organic layer.

According to some example embodiments, the functional layer may include a hole transport region on the first electrode, a light-emitting layer on the hole transport region, and an electron transport region on the light-emitting layer.

According to some example embodiments, at least one of the hole transport region or the electron transport region may include the first material.

According to some example embodiments, the functional layer may include a first emissive stack having a first hole transport region, a first light-emitting layer on the first hole transport region, and a first electron transport region on the first light-emitting layer, The functional layer may also include a charge generation layer on the first emissive stack, and a second emissive stack having a second hole transport region, a second light-emitting layer on the second hole transport region, and a second electron transport region on the second light-emitting layer.

According to some example embodiments, at least a portion of the charge generation layer may be a cut shape in the non-pixel region.

According to some example embodiments, the display panel may further include an encapsulation layer on the plurality of light-emitting elements and the pixel-defining film.

Alternatively or additionally according to some example embodiments, an electronic apparatus capable of providing an image includes a window, a display panel under the window, and in which a plurality of pixel regions and a non-pixel region surrounding the pixel regions are defined, and an external case coupled to the window and configured to accommodate the display panel. The display panel includes a pixel-defining film at least partly overlapping the non-pixel region, and in which a pixel opening corresponding to each of the plurality of pixel regions and a valley pattern depressed from an upper surface along a thickness direction are defined, a plurality of light-emitting elements of which at least a portion is in the pixel opening, and in which a depression pattern corresponding to the valley pattern is defined, and an organic layer containing a first material and at least partially fill at least a portion of the depression pattern. A glass transition temperature of the first material is 50° C. to 90° C.

Alternatively or additionally according to some example embodiments, a method of manufacturing a display panel having a plurality of pixel regions and a non-pixel region surrounding the pixel regions, the method includes providing a preliminary display module having a plurality of preliminary light-emitting elements and a pixel-defining film which overlaps the non-pixel region and in which a valley pattern depressed along a thickness direction is defined, forming a first preliminary organic layer on the preliminary display module, forming a second preliminary organic layer by heat treating the first preliminary organic layer at a first temperature, and forming an organic layer by removing, from an upper surface of the preliminary display module, at least a portion of the second preliminary organic layer overlapping the pixel region. The first temperature is 50° C. to 90° C.

In some example embodiments, the method of manufacturing a display panel according may further include forming, on the organic layer and the preliminary display module, an auxiliary electrode layer to overlap the plurality of pixel regions and the non-pixel region after the forming of the organic layer.

In some example embodiments, the organic layer may be composed of a first material, and a glass transition temperature of the first material may be equal to or more than the first temperature.

In some example embodiments, a material contained in the first preliminary organic layer may be in a glassy state, and a material contained in the second preliminary organic layer may be in a rubbery state.

### BRIEF DESCRIPTION OF THE FIGURES

The accompanying drawings are included to provide a further understanding of inventive concepts, and are incorporated in and constitute a part of this specification. The drawings illustrate some example embodiments and, together with the description, serve to explain principles of inventive concepts. In the drawings:

FIG. 1A is an assembled perspective view of an electronic apparatus according to some example embodiments;

FIG. 1B is an exploded perspective view of an electronic apparatus according to some example embodiments;

FIG. 2A is an assembled perspective view of an electronic apparatus according to some example embodiments;

FIG. 2B is an exploded perspective view of an electronic apparatus according to some example embodiments;

FIG. 3 is a block diagram of an electronic apparatus according to some example embodiments;

FIG. 4 is a cross-sectional view of a display module according to some example embodiments;

FIG. 5 is an enlarged plan view of a portion of a display panel according to some example embodiments;

FIG. 6 is a cross-sectional view of a portion of a display panel according to some example embodiments;

FIGS. 7A and 7B are each a cross-sectional view of a light-emitting element according to some example embodiments;

FIG. 8A is an enlarged cross-sectional view of a portion of a display panel according to some example embodiments;

FIG. 8B is an enlarged cross-sectional view of a portion of a display panel according to some example embodiments;

FIG. 9 is a flowchart illustrating a method of manufacturing a display panel according to some example embodiments; and

FIGS. 10A to 10E are cross-sectional views illustrating a part of steps of a method of manufacturing a display panel according to some example embodiments.

### DETAILED DESCRIPTION

Hereinafter, some example embodiments are described with reference to the drawings.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. Also, in the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element from another element. For instance, a first element discussed below could be termed a second element without departing from the scope of the inventive concept. Similarly, a second element could be termed a first element. In this specification, the singular expressions “a”, “an” and “the” are intended to include the plural forms as well, unless the context clearly indicates otherwise.

In addition, the terms “below”, “under”, “on the lower side”, “above”, “over”, “on the upper side”, or the like may be used to describe the relationships between the elements illustrated in the drawings. These terms have relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components, or combinations thereof, but do not preclude the possibility of the presence or addition of one or more other features, numbers, steps, operations, elements, components, and/or combinations thereof.

In this specification, when an element is referred to as being “directly disposed on” another layer, film, region, board, etc., there are no intervening layer, film, region, board, etc., present. For example, the wording “directly disposed” means that an additional member such as an adhesive member, or the like may not be used between two layers or two members.

Unless otherwise defined, all terms (including technical and scientific terms) used herein have the same meaning as commonly understood by one of ordinary skills in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an electronic apparatus according to some example embodiments is described with reference to the drawings.

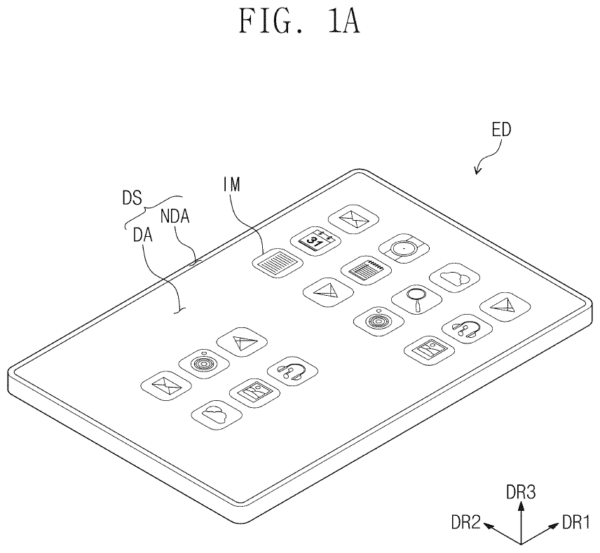

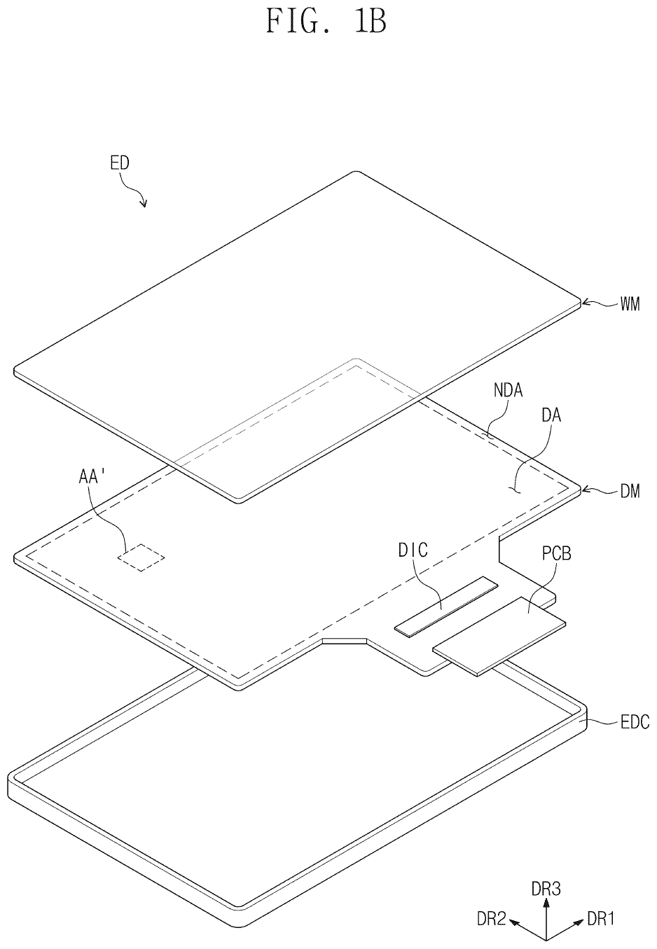

FIG. 1A is an assembled perspective view of an electronic apparatus according to some example embodiments. FIG. 1B is an exploded perspective view of an electronic apparatus according to some example embodiments.

Referring to FIG. 1A, an electronic apparatus ED may be activated in response to an electrical signal. The electronic apparatus ED may display an image IM and may sense an external input. The electronic apparatus ED may include various examples. For instance, the electronic apparatus ED may include one or more of a tablet PC, a laptop, a computer, a smart phone, a television, and the like. However, embodiments of the electronic apparatus ED are examples, and are not limited to any one embodiment unless deviating from the idea of inventive concepts.

The electronic apparatus ED may be rigid and/or flexible. The wording “flexible” means a bendable property. For instance, the flexible electronic apparatus ED may include a curved device, a rollable device, or a foldable device.

The electronic apparatus ED may display the image IM toward a third direction DR3 on a display surface DS that is parallel to each of a first direction DR1 and a second direction DR2. The display surface DS on which the image IM is displayed may correspond to a front surface of the electronic apparatus ED, and may correspond to a front surface FS of a window WM. As used herein, the wording “a region/portion corresponds to a region/portion” means that “a region/portion overlaps a region/portion”, and the meaning is not limited to having the same area. Hereinafter, the same reference numerals or symbols will be used for the display surface and front surface of the electronic apparatus ED, and the front surface of the window WM. The image IM may include a static image as well as a dynamic image. In FIG. 1A, a plurality of icons are illustrated as an example of the image IM.

In some example embodiments, a front surface (or top surface) and a rear surface (or bottom surface) of each member are defined on the basis of a direction in which the image IM is displayed. The front surface and the rear surface may be opposed to each other in the third direction DR3, and a normal (or perpendicular) direction of each of the front surface and the rear surface may be parallel to the third direction DR3. A spaced distance in the third direction DR3 between the front surface and the rear surface may correspond to a thickness of the electronic apparatus ED in the third direction DR3. Meanwhile, the directions indicated by the first to third directions DR1, DR2, and DR3 may have a relative concept and may thus be changed to other directions. Hereinafter, first to third directions may be the directions respectively indicated by the first to third directions DR1, DR2, and DR3, and may thus be denoted as the same reference numerals or symbols. In addition, as used herein, the wording “on a plane” may mean “when viewed on a plane defined by the first direction DR1 and the second direction DR2”.

The electronic apparatus ED according to some example embodiments may sense an input, such as a user's input applied from the outside. The user's input may include various types of external inputs such as a part of the user body, light, heat, or pressure. The user's input may be provided in various forms. The electronic apparatus ED may alternatively or additionally sense the user's input applied to a side surface and/or rear surface of the electronic apparatus ED depending on a structure of the electronic apparatus ED, and is not limited to any one embodiment.

As illustrated in FIG. 1B, an electronic apparatus ED may include a window WM, a display module DM, and an external case EDC. In some example embodiments, the window WM and the external case EDC are coupled to constitute, or to be included in, an exterior of the electronic apparatus ED. In some example embodiments, the external case EDC, the display module DM, and the window WM may be sequentially stacked along a third direction DR3.

The window WM may include an optically transparent material. Alternatively or additionally, the window WM may include an insulating panel. For instance, the window WM may be composed of glass, plastic, or a combination thereof.

As mentioned above, the front surface FS of the window WM defines the front surface of the electronic apparatus ED.

The window WM may include a bezel region and a transmissive region. The transmissive region may be an optically transparent region. For example, the transmissive region may be a region having visible light transmittance of about 90% or more.

The bezel region may be a region having relatively lower light transmittance than the transmissive region. The bezel region defines a shape of the transmissive region. The bezel region may be adjacent to the transmissive region, and may surround the transmissive region. The bezel region may have a color, such as but not limited to predetermined color. The bezel region may overlap a non-display region NDA of the display module DM. The bezel region may cover the non-display region NDA of the display module DM to prevent the non-display region NDA from being visible from the outside. Meanwhile, this is illustrated, and the bezel region may be omitted in the window WM according to some example embodiments.

The display module DM includes a display region DA and the non-display region NDA. The display region DA may be or may correspond to a region for providing an image IM, and the non-display region NDA may be or may correspond to a region where a driving circuit or driving wiring is disposed. Light-emitting elements of each of a plurality of pixels may be disposed in the display region DA. The non-display region NDA may be adjacent to the display region DA. The non-display region NDA may surround or at least partially surround the display region DA. The display module DM may include a driving chip DIC disposed on the non-display region NDA. The display module DM may further include a printed circuit board PCB coupled to the non-display region NDA. The printed circuit board PCB may be electrically connected to pads disposed in the non-display region NDA through an anisotropic conductive adhesive layer.

The driving chip DIC may include driving elements, for example, a data driving circuit, for driving the pixels of the display module DM. FIG. 1B illustrates a structure in which the driving chip DIC is mounted on the display module DM, but example embodiments are not limited thereto. For example, the driving chip DIC may be mounted on the printed circuit board PCB.

The external case EDC may accommodate the display module DM, and may be coupled to the window WM. The external case EDC may protect or at least partially protect the components, such as the display module DM, accommodated inside the external case EDC.

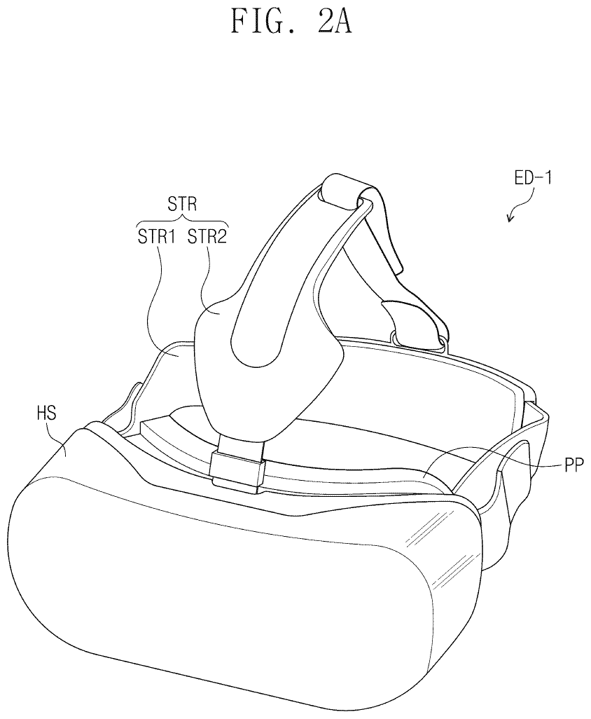

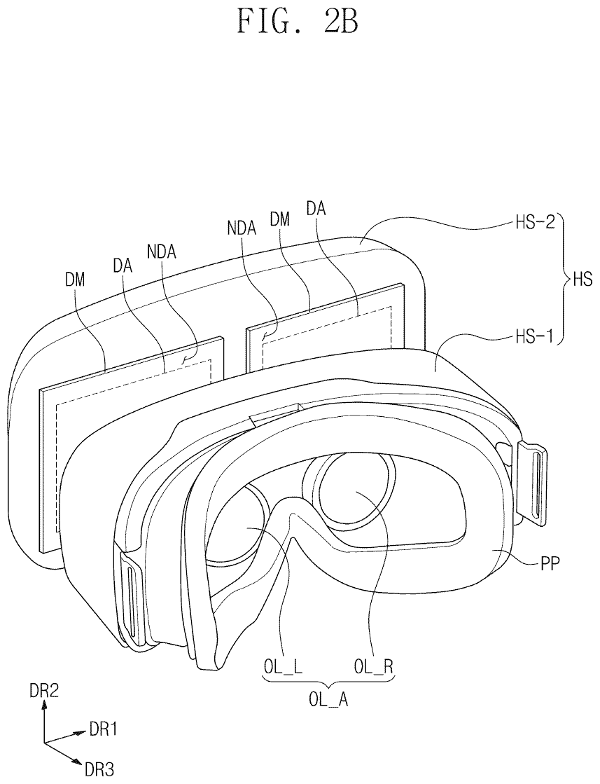

FIG. 2A is an assembled perspective view of an electronic apparatus according to some example embodiments. FIG. 2B is an exploded perspective view of an electronic apparatus according to some example embodiments.

An electronic apparatus ED-1 according to some example embodiments illustrated in FIGS. 2A and 2B may be activated in response to an electrical signal, and may be or may include (or be included in) a wearable apparatus. The wearable apparatus may be worn on a user's body, and may include a head mounted display (HMD) device for implementing extended reality (XR). FIGS. 2A and 2B illustrate that the electronic apparatus ED-1 is a head mounted display device, but some example embodiments are not limited thereto.

The electronic apparatus ED-1 according to some example embodiments illustrated in FIGS. 2A and 2B may be a display device that is worn on a user's head. The electronic apparatus ED-1 may provide an image with the user's actual peripheral vision blocked. The user wearing the electronic apparatus ED-1 may be more easily immersed in virtual reality.

The electronic apparatus ED-1 may include a body part HS, a strap part STR, a cushion part PP, and a display module DM. Although not illustrated, the electronic apparatus ED-1 may include various sensors, a camera, and the like.

The body part HS may be worn on the user's head. The display module DM for displaying an image, and an acceleration sensor (not illustrated) may be accommodated inside the body part HS. The acceleration sensor may sense user's movements, and may transmit a predetermined signal to the display module DM. Accordingly, the display module DM may provide an image corresponding to a change in user gaze. Thus, the user may experience virtual reality just like actual reality. What has been described with reference to FIG. 1B may be equally applied to the display module DM. In addition, a configuration of the display module DM included in the electronic apparatus ED-1 according to an embodiment may be provided to include a component different from what is illustrated in FIG. 1B so as to comply with a property of the wearable apparatus.

Components having various functions other than what is disclosed above may be accommodated in the body part HS. For example, an operation part (not illustrated) and the like for adjusting the volume, screen brightness, etc., may further be disposed outside the body part HS. The operation part may be provided as a physical button, a touch sensor, or the like. In addition, a proximity sensor (not illustrated) for determining whether the user is wearing or not may also be accommodated in the body part HS. Additionally, an external display panel may further be disposed in the body part HS.

The body part HS may be separated into a body portion HS-1 and a cover portion HS-2. FIG. 2B illustrates a shape in which the body portion HS-1 and the cover portion HS-2 are separated, but some example embodiments are not limited thereto. For example, the body portion HS-1 and the cover portion HS-2 may be provided as an integrated form, and may not be separated from each other.

The display modules DM may be disposed between the body portion HS-1 and the cover portion HS-2. The display modules DM may each provide an image through a display region DA. The display modules DM may each include a non-display region NDA surrounding the display region DA. Meanwhile, in some example embodiments, the non-display region NDA may be disposed only at one side of the display region DA, or may be omitted.

In FIG. 2B, it is illustrated that a left-eye image and a right-eye image are provided respectively from the display modules DM that are separated from each other, but some example embodiments are not limited thereto. For instance, the left-eye image and the right-eye image may be displayed through one display module. The display modules DM may be driven by separate driving parts. However, some example embodiments are not limited thereto, and the display modules DM may be driven by one driving part. The display modules DM generate an image corresponding to input image data.

The strap part STR may be coupled to the body part HS to allow the body part HS to be easily worn on the user. The strap part STR may include a main strap STR1 and an upper strap STR2.

The main strap STR1 may be worn along the user's head circumference. The main strap STR1 may fasten the body part HS to the user such that the body part HS is closely attached to the user's head. The upper strap STR2 may connect the body part HS and the main strap STR1 along an upper portion of the user's head. The upper strap STR2 may prevent or reduce the likelihood of and/or impact from the body part HS from sliding off. In addition, the upper strap STR2 may disperse the load of the body part HS, thereby further improving wearing comfort of the user.

The strap part STR may be deformed into various shapes other than the shape illustrated in FIG. 2A as long as being capable of fastening the body part HS to the user. For instance, in some example embodiments, the upper strap STR2 may be omitted. In addition, in still some example embodiments, the strap part STR may be deformed into various shapes such as a helmet coupled to the body part HS, or temples of glasses coupled to the body part HS.

The cushion part PP may be disposed between the body part HS and the user's head. The cushion part PP may be composed of a material of which the shape is freely modified. For example, the cushion part PP may be formed of a polymer resin (for example, one or more of polyurethane, polycarbonate, polypropylene, and polyethylene), or may be formed of a sponge obtained by foaming/molding one or more of a rubber solution, a urethane-based material, or an acrylate-based material. However, the material that constitutes the cushion part PP is not limited thereto.

The cushion part PP may allow the body part HS to be closely attached to the user, thereby improving wearing comfort of the user. The cushion part PP may be detachable/attachable from/to the body part HS. The cushion part PP may be omitted in some example embodiments.

An optical system OL_A may be disposed inside the body portion HS-1 of the body part HS. The optical system OL_A may enlarge an image provided from the display modules DM. The display modules DM may each display an image in a third direction DR3 through the display region DA that is parallel to a first direction DR1 and a second direction DR2 crossing the first direction DR1. The optical system OL_A may be located to be spaced apart from the display modules DM in the third direction DR3. The optical system OL_A may be disposed between the display modules DM and the user's eyes. The optical system OL_A may include a right-eye optical system OL_R and a left-eye optical system OL_L. The left-eye optical system OL_L may enlarge and provide an image to a user's left pupil, and the right-eye optical system OL_R may enlarge and provide an image to a user's right pupil.

The left-eye optical system OL_L may be located to be spaced apart from the right-eye optical system OL_R in the first direction DR1. A distance between the right-eye optical system OL_R and the left-eye optical system OL_L may be adjustable according to the distance between the user's both eyes. Furthermore, a distance between the optical system OL_A and the display modules DM may also be adjustable depending on the user's eyesight.

The optical system OL_A may be or may include an aspherical lens having a convex shape. For instance, the optical system OL_A may be or may include a pancake lens, but is not particularly limited thereto. In some example embodiments, it is illustrated that the left-eye optical system OL_L and the right-eye optical system OL_R are each composed of only one lens, but some example embodiments are not limited thereto. For example, the left-eye optical system OL_L and the right-eye optical system OL_R may each include a plurality of lenses.

Meanwhile, the electronic apparatus ED-1 according to some example embodiments illustrated in FIGS. 2A and 2B may further include a window (not illustrated) disposed on the display module DM. What has been described with reference to FIG. 1B may be equally applied to the window (not illustrated), or the window may be provided to include a configuration different from what has been illustrated in FIG. 1B so as to comply with a property of the wearable apparatus. The window (not illustrated) may include a base material, a reflection-reducing layer, and the like.

The display module DM included in the electronic apparatus ED-1 according to some example embodiments may have a high-resolution property. For instance, the display module DM according to some example embodiments may have ultra-high resolution display quality of about 3000 ppi or more.

FIG. 3 is a block diagram of an electronic apparatus according to some example embodiments.

An electronic apparatus ED outputs various pieces of information through a display module 14 within an operation system. When a processor 11 executes an application stored in a memory 12, the display module 14 provides application information to a user through a display panel 14-1. Meanwhile, the display module 14 in FIG. 3 may refer to the aforementioned display module DM, and the display panel 14-1 may refer to a display panel DP to be described later.

The processor 11 acquires an external input through an input module 13 or a sensor module 16-1, and executes an application corresponding to the external input. For example, when a user chooses a camera icon displayed on the display panel 14-1, the processor 11 acquires a user's input through an input sensor 16-12, and activates a camera module 17-11. The processor 11 transmits, to the display module 14, image data corresponding to a captured image acquired by the camera module 17-11. The display module 14 may display an image corresponding to the captured image through the display panel 14-1.

As another example, when personal information authentication is executed in the display module 14, a fingerprint sensor 16-11 acquires, as input data, fingerprint information which has been input. The processor 11 compares the input data acquired through the fingerprint sensor 16-11 with authentication data stored in the memory 12, and executes an application according to the result of comparison. The display module 14 may display, through the display panel 14-1, information executed according to the logic of the application.

As another example, when a music streaming icon displayed on the display module 14 is chosen, the processor 11 acquires a user's input through the input sensor 16-12, and activates a music streaming application stored in the memory 12. When a music execution command is input in the music streaming application, the processor 11 activates a sound output module 16-3 and provides, to the user, sound information corresponding to the music execution command.

In the above, an operation of the electronic apparatus ED has been briefly described. Components of the electronic apparatus ED will be described in detail below. Some of the components of the electronic apparatus ED to be described below may be integrated and provided as a single component, and one component may be divided into two or more components.

Referring to FIG. 3, the electronic apparatus ED may communicate with an external electronic apparatus OD through a network (for example, a short-range wireless communication network or long-range wireless communication network). According to some example embodiments, the electronic apparatus ED may include the processor 11, the memory 12, the input module 13, the display module 14, a power supply module 15, an embedded module 16, and an external module 17. According to some example embodiments, at least one of the aforementioned components of the electronic apparatus ED may be omitted, or one or more other components may be added. According to some example embodiments, some components (for example, the sensor module 16-1, an antenna module 16-2, or the sound output module 16-3) among the aforementioned components may be integrated into another component (for example, the display module 14).

The processor 11 may execute software to control at least one other component (for example, a hardware or software component), of the electronic apparatus ED, which is connected to the processor 11, and may perform various types of data processing or computations. According to some example embodiments, as at least part of the data processing or computations, the processor 11 may store data or a command received from other components (for example, the input module 13, the sensor module 16-1, or a communication module 17-13) in a volatile memory 12-1, and may process the command or data stored in the volatile memory 12-1, and result data may be stored in a non-volatile memory 12-2.

The processor 11 may include a main processor 11-1 and an auxiliary processor 11-2. The main processor 11-1 may include at least one of a central processing unit (CPU) 11-11 or an application processor (AP). The main processor 11-1 may further include at least any one among a graphic processing unit (GPU) 11-12, a communication processor (CP), and an image signal processor (ISP). The main processor 11-1 may further include a neural processing unit (NPU) 11-13. The neural processing unit may be a processor specialized in processing an artificial intelligence model, and the artificial intelligence model may be generated through machine learning. The artificial intelligence model may include a plurality of artificial neural network layers. The artificial neural network may be or may include a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-networks, or a combination of two or more thereof, but is not limited to the above examples. The artificial intelligence model may additionally or alternatively include a software structure in addition to a hardware structure. At least two among the aforementioned processing units and the processors may be implemented as one integrated component (for example, a single chip) or may be respectively implemented as individual components (for example, a plurality of chips).

The auxiliary processor 11-2 may include a controller 11-21. The controller 11-21 may include an interface conversion circuit and a timing control circuit. The controller 11-21 may receive an image signal from the main processor 11-1, may convert a data format of the image signal to comply with an interface specification for the display module 14, and then output image data. The controller 11-21 may output various control signals that are necessary to drive the display module 14.

The auxiliary processor 11-2 may further include a data conversion circuit 11-22, a gamma correction circuit 11-23, a rendering circuit 11-24, and the like. The data conversion circuit 11-22 may receive the image data from the controller 11-21, and may compensate for the image data to display an image having a desired luminance according to the properties of the electronic apparatus ED, a user's setting, or the like, or may convert the image data for reduction in power consumption, compensation for afterimage, or the like. The gamma correction circuit 11-23 may convert the image data, a gamma reference voltage, or the like such that the image displayed in the electronic apparatus ED has a desired gamma property. The rendering circuit 11-24 may receive the image data from the controller 11-21, and may render the image data in consideration of a pixel arrangement, etc., of the display panel 14-1 applied to the electronic apparatus ED. At least one of the data conversion circuit 11-22, the gamma correction circuit 11-23, or the rendering circuit 11-24 may be integrated into another component (for example, the main processor 11-1 or the controller 11-21). At least one of the data conversion circuit 11-22, the gamma correction circuit 11-23, or the rendering circuit 11-24 may also be integrated into a data driver 14-3 to be described later.

The memory 12 may store various data which are used by at least one component (for example, the processor 11 or the sensor module 16-1) of the electronic apparatus ED, and may store input data or output data about commands related thereto. The memory 12 may include at least one of the volatile memory 12-1 or the non-volatile memory 12-2.

The input module 13 may receive commands or data, which will be used in a component (for example, the processor 11, the sensor module 16-1, or the sound output module 16-3) of the electronic apparatus ED, from the outside (for example, a user or the external electronic apparatus OD) of the electronic apparatus ED.

The input module 13 may include a first input module 13-1 to which commands or data are input from a user and a second input module 13-2 to which commands or data are input from the external electronic apparatus OD. The first input module 13-1 may include a microphone, a mouse, a keyboard, a key (for example, a button) or a pen (for example, a passive pen or an active pen). The second input module 13-2 may support a designated protocol that allows wired or wireless connection with the external electronic apparatus OD. According to some example embodiments, the second input module 13-2 may include a high definition multimedia interface (HDMI), a universal serial bus (USB) interface, an SD card interface, or an audio interface. The second input module 13-2 may include a connector, for example, an HDMI connector, a USB connector, an SD card connector, or an audio connector (for example, a headphone connector), which is capable of physical connection with the external electronic apparatus OD.

The display module 14 visually provides information to a user. The display module 14 may include a display panel 14-1, a scan driver 14-2, and a data driver 14-3. The display module 14 may further include a window, a chassis, and a bracket for protecting the display panel 14-1.

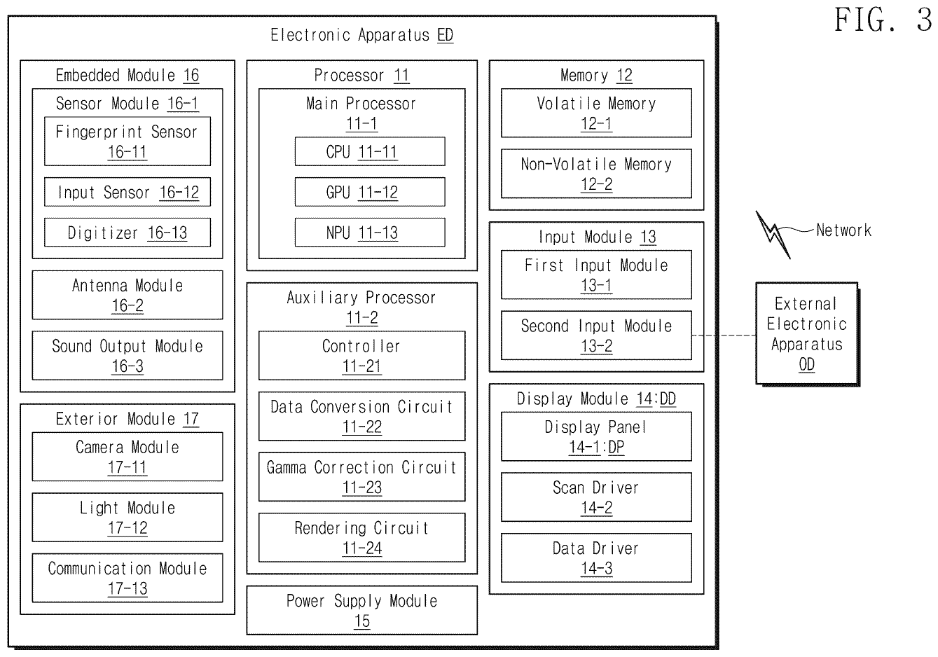

The display panel 14-1 may include a liquid crystal display panel, an organic light-emitting display panel, or an inorganic light-emitting display panel, and a type of the display panel 14-1 is not particularly limited. The display panel 14-1 may be a rigid display panel, or a flexible display panel that is rollable or foldable. The display module 14 may further include a supporter for supporting the display panel 14-1, a bracket, a heat dissipation member, or the like. A detailed description of the display panel 14-1 will be described later with reference to FIG. 4 and below.

The scan driver 14-2 may be mounted as a driving chip on the display panel 14-1. In addition, the scan driver 14-2 may be integrated into the display panel 14-1. For example, the scan driver 14-2 may include an amorphous silicon TFT gate (ASG) driver circuit, a low temperature polycrystalline silicon (LTPS) TFT gate driver circuit, or an oxide semiconductor TFT gate (OSG) driver circuit, which is integrated in the display panel 14-1. The scan driver 14-2 receives a control signal from the controller 11-21, and outputs a scan signal to the display panel 14-1 in response to the control signal.

The display panel 14-1 may further include an emission driver. The emission driver outputs an emission control signal to the display panel 14-1 in response to the control signal received from the controller 11-21. The emission driver may be formed separately from the scan driver 14-2, or may be integrated into the scan driver 14-2.

The data driver 14-3 receives the control signal from the controller 11-21, converts the image data into an analog voltage (for example, a data voltage) in response to the control signal, and then outputs data voltages to the display panel 14-1.

The data driver 14-3 may be integrated into another component (for example, the controller 11-21). The functions of the interface conversion circuit and the timing control circuit of the aforementioned controller 11-21 may also be integrated into the data driver 14-3.

The display module 14 may further include an emission driver, a voltage generation circuit, and the like. The voltage generation circuit may output various voltages that are necessary to drive the display panel 14-1.

The power supply module 15 supplies power to the components of the electronic apparatus ED. The power supply module 15 may include a battery for charging a power voltage. The battery may include a non-rechargeable primary cell, a rechargeable secondary cell, or a fuel cell. The power supply module 15 may include a power management integrated circuit (PMIC). The PMIC supplies optimized power to each of the aforementioned modules and modules to be described later. The power supply module 15 may include a wireless power transmission and reception member that is electrically connected to the battery. The wireless power transmission and reception member may include a plurality of antenna radiators in a coil shape.

The electronic apparatus ED may further include the embedded module 16 and the external module 17. The embedded module 16 may include the sensor module 16-1, the antenna module 16-2, and the sound output module 16-3. The external module 17 may include the camera module 17-11, a light module 17-12, and the communication module 17-13.

The sensor module 16-1 may sense an input applied by a part of the user body or an input applied by a pen of the first input module 13-1, and may generate an electrical signal or a data value corresponding to the input. The sensor module 16-1 may include at least any one among the fingerprint sensor 16-11, the input sensor 16-12, and a digitizer 16-13.

The fingerprint sensor 16-11 may generate a data value corresponding to a user's fingerprint. The fingerprint sensor 16-11 may include any one of an optical fingerprint sensor or a capacitive fingerprint sensor.

The input sensor 16-12 may generate a data value corresponding to coordinate information about the input applied by the pen or the input applied by a part of the user body. The input sensor 16-12 may generate, as the data value, an amount of change in capacitance caused by the input. The input sensor 16-12 may sense an input applied by the passive pen, or may transmit/receive data to/from the active pen.

The input sensor 16-12 may also measure bio-signals such as blood pressure, hydration, or body fat. For example, when a user does not move during a certain period of time while touching a sensor layer or a sensing panel with a part of the user body, the input sensor 16-12 may sense the bio-signals on the basis of changes in electric field caused by the part of the user body, and output, to the display module 14, information desired by the user.

The digitizer 16-13 may generate a data value corresponding to coordinate information about the input applied by the pen. The digitizer 16-13 may generate, as the data value, an amount of electromagnetic changes caused by the input. The digitizer 16-13 may sense an input applied by the passive pen, or may transmit/receive data to/from the active pen.

At least one among the fingerprint sensor 16-11, the input sensor 16-12, and the digitizer 16-13 may also be implemented as a sensor layer 200 (see FIG. 4) formed on the display panel 14-1 through a continuous process. The fingerprint sensor 16-11, the input sensor 16-12, and the digitizer 16-13 may be disposed on the display panel 14-1, and any one among the fingerprint sensor 16-11, the input sensor 16-12, and the digitizer 16-13, for example, the digitizer 16-13 may be disposed under the display panel 14-1.

At least two among the fingerprint sensor 16-11, the input sensor 16-12, and the digitizer 16-13 may be formed to be integrated into a single sensing panel through the same process. When integrated into the single sensing panel, the sensing panel may be disposed between the display panel 14-1 and a window disposed on the display panel 14-1. According to some example embodiments, the sensing panel may also be disposed on the window, and the location of the sensing panel is not particularly limited.

At least one among the fingerprint sensor 16-11, the input sensor 16-12, and the digitizer 16-13 may be embedded in the display panel 14-1. For example, at least one among the fingerprint sensor 16-11, the input sensor 16-12, and the digitizer 16-13 may be simultaneously formed through a process for forming elements (for example, a light-emitting element, a transistor, and/or the like) included in the display panel 14-1.

Alternatively or additionally, the sensor module 16-1 may generate an electrical signal or a data value corresponding to an internal state or an external state of the electronic apparatus ED. For example, the sensor module 16-1 may further include one or more of a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illumination sensor.

The antenna module 16-2 may include one or more antennae for transmitting a signal or power to the outside or receiving a signal or power from the outside. According to some example embodiments, the communication module 17-13 may transmit a signal to the external electronic apparatus, or receive a signal from the external electronic apparatus through an antenna suitable for a communication method. An antenna pattern of the antenna module 16-2 may be integrated into one component (for example, the display panel 14-1) of the display module 14, the input sensor 16-12, or the like.

The sound output module 16-3 may be or may include (or be included in) a unit for outputting a sound signal to the outside of the electronic apparatus ED, and for example, may include a speaker that is used for general purposes such as multimedia playback or recording playback, and a receiver that is used exclusively for receiving phone calls. According to some example embodiments, the receiver may be formed integrally with or separately from the speaker. A sound output pattern of the sound output module 16-3 may be integrated into the display module 14.

The camera module 17-11 may capture still images and moving images. According to some example embodiments, the camera module 17-11 may include one or more lenses, an image sensor, or an image signal processor. The camera module 17-11 may further include an infrared camera capable of measuring presence/absence of a user, a user's location, user's gaze, and the like.

The light module 17-12 may provide light. The light module 17-12 may include a light-emitting diode and/or a xenon lamp. The light module 17-12 may operate in conjunction with or operate independently from the camera module 17-11.

The communication module 17-13 may assist in establishment of a wired and/or wireless communication channel between the electronic apparatus ED and the external electronic apparatus OD, and assist in communication through the established communication channel. The communication module 17-13 may include any one or more of among a wireless communication module such as one or more of a cellular communication module, a short-range wireless communication module, or a global navigation satellite system (GNSS) communication module and a wired communication module such as one or more of a local area network (LAN) communication module or a power line communication module, or may include both the wireless communication module and the wired communication module. The communication module 17-13 may communicate with the external electronic apparatus OD through a short-range communication network such as one or more of Bluetooth, Wi-Fi direct, or infrared data association (IrDA), and/or through a long-range communication network such as a cellular network, Internet, or a computer network (for example, LAN or WAN). Various types of the communication modules 17-13 described above may be implemented as a single chip or may be respectively implemented as individual chips.

The input module 13, the sensor module 16-1, the camera module 17-11, and the like may be used for controlling the operation of the display module 14 in conjunction with the processor 11.

The processor 11 outputs commands and/or data to the display module 14, the sound output module 16-3, the camera module 17-11, or the light module 17-12, on the basis of the input data received from the input module 13. For example, the processor 11 may generate image data corresponding to the input data applied through one or more of the mouse, the active pen, or the like and output the image data to the display module 14, and/or may generate command data corresponding to the input data and output the command data to the camera module 17-11 or the light module 17-12. When the input data are not received for a certain period of time from the input module 13, the processor 11 may switch an operation mode of the electronic apparatus ED to a low power mode or a sleep mode, thereby reducing power consumed in the electronic apparatus ED.

The processor 11 outputs commands and/or data to the display module 14, the sound output module 16-3, the camera module 17-11, or the light module 17-12, on the basis of sensed data received from the sensor module 16-1. For example, the processor 11 may compare authentication data applied by the fingerprint sensor 16-11 with the authentication data stored in the memory 12, and then may execute an application according to the result of comparison. The processor 11 may, on the basis of the sensed data detected by the input sensor 16-12 and/or the digitizer 16-13, execute a command or output the corresponding image data to the display module 14. When a temperature sensor is included in the sensor module 16-1, the processor 11 may receive temperature data about the temperature measured by the sensor module 16-1, and may further perform luminance correction, etc., on the image data, on the basis of the temperature data.

The processor 11 may receive measured data about presence/absence of one or more of a user, a user's location, user's gaze, or the like from the camera module 17-11. The processor 11 may further perform luminance correction, etc., on the image data on the basis of the measured data. For example, the processor 11 which has determined the presence or absence of a user through the input from the camera module 17-11 may, to the display module 14, output image data with luminance corrected through the data conversion circuit 11-22 or the gamma correction circuit 11-23.

At least two, some, or all components of the above components may be connected to each other through a communication method between peripheral devices, for example, one or more of a bus, general purpose input/output (GPIO), a serial peripheral interface (SPI), a mobile industry processor interface (MIPI), or an ultra-path interconnect (UPI) link, and may mutually exchange signals (for example, commands or data). The processor 11 may communicate with the display module 14 through a mutually agreed-upon interface, and for example, any one of the aforementioned communication methods may be used. Some example embodiments are not limited to the aforementioned communication methods.

FIG. 4 is a cross-sectional view of a display module according to some example embodiments.

Referring to FIG. 4, a display module DM may include a display panel DP and an input sensing unit ISU. The display panel DP may be or may include (or be include in) a component which substantially generates the image IM (see FIG. 1A). The image IM (see FIG. 1A) which the display panel DP generates may be visible to a user from the outside through a display region DA.

The display panel DP may be, may include, or be included in an emissive display panel, and is not particularly limited. For example, the display panel DP may be, include, or be included in an organic light-emitting display panel or an inorganic light-emitting display panel. A light-emitting layer of the organic light-emitting display panel may be or may correspond to a display panel including an organic light-emitting material. A light-emitting layer of the inorganic light-emitting display panel may be a display panel including quantum dots, quantum rods, or a micro LED. Hereinafter, the display panel DP will be described as an organic light-emitting display panel.

The input sensing unit ISU may be disposed on the display panel DP. The input sensing unit ISU may sense an external input applied from the outside. The external input may include various types of inputs provided from the outside of the electronic apparatus ED (see FIG. 1A). The external input that is applied from the outside may be provided in various types. For instance, the external input may include not only a touch by a user's body part such as a hand but also an external input (for example, hovering) applied by approaching or becoming adjacent to the electronic apparatus ED (see FIG. 1A) at a particular distance, such as at a predetermined distance. Alternatively or additionally, the external input may have various types such as one or more of force, pressure, or light, and is not limited to any one embodiment.

The input sensing unit ISU may be formed on the display panel DP through a continuous process. In this case, the input sensing unit ISU may be directly disposed on the display panel DP. Meanwhile, as used herein, the wording “a component B is directly disposed on a component A” may mean that a third component is not disposed between the component A and the component B. For example, an adhesive layer may not be disposed between the input sensing unit ISU and the display panel DP.

The display panel DP may include a base layer BL, a circuit element layer DP-CL disposed on the base layer BL, a display element layer DP-OLED, and an upper insulation layer TFL.

The base layer BL may provide a base surface on which the circuit element layer DP-CL, the display element layer DP-OLED, and the upper insulation layer TFL are disposed. The base layer BL may be or may include a rigid substrate and/or a flexible substrate capable of bending, folding, rolling, etc. The base layer BL may be, may include, or may be included in one or more of a glass substrate, a metal substrate, a polymer substrate, or the like. However, some example embodiments are not limited thereto, and the base layer BL may include an inorganic layer, an organic layer, or a composite material layer.

The base layer BL may have a multi-layered structure. For instance, the base layer BL may include a first synthetic resin layer, a single- or multi-layered inorganic layer, and a second synthetic resin layer disposed on the single- or multi-layered inorganic layer. The first and second synthetic resin layers may each include a polyimide-based resin such as the same or different polyimide-based resin, and are not particularly limited.

The circuit element layer DP-CL may be disposed on the base layer BL. The circuit element layer DP-CL may include a plurality of insulation layers, a plurality of conductive layers, and a semiconductor layer. The plurality of conductive layers of the circuit element layer DP-CL may constitute signal lines and/or a control circuit of a pixel.

The display element layer DP-OLED may be disposed on the circuit element layer DP-CL. The display element layer DP-OLED may include light-emitting elements. The display element layer DP-OLED may include, for example, organic light-emitting elements. However, this is an example, and the display element layer DP-OLED according to some example embodiments may include inorganic light-emitting elements, organic-inorganic light-emitting elements, or a liquid crystal layer.

The upper insulation layer TFL may include a capping layer to be described later. And a thin-film encapsulation layer. The upper insulation layer TFL may include an organic layer and a plurality of inorganic layers which seal the organic layer.

The upper insulation layer TFL may be disposed on the display element layer DP-OLED to protect or at least partially protect the display element layer DP-OLED from moisture, oxygen, and foreign matters such as dust particles. The upper insulation layer TFL may seal the display element layer DP-OLED to block moisture and oxygen which are introduced to the display element layer DP-OLED. The upper insulation layer TFL may include at least one inorganic layer. The upper insulation layer TFL may include an organic layer and a plurality of inorganic layers which seal the organic layer. The upper insulation layer TFL may include a sequentially stacked structure of inorganic layer/organic layer/inorganic layer.

The input sensing unit ISU is disposed on the upper insulation layer TFL. The input sensing unit ISU may be formed on the upper insulation layer TFL through a continuous process. The input sensing unit ISU may be directly disposed on the display panel DP. For example, a separate adhesive member may not be disposed between the input sensing unit ISU and the display panel DP. The input sensing unit ISU may be disposed to be in contact with an inorganic layer that is disposed at an uppermost portion of the upper insulation layer TFL.

Although not illustrated separately, the display module DM according to some example embodiments may further include a protection member disposed on a lower surface of the display panel DP, and an anti-reflection member disposed on an upper surface of the input sensing unit ISU. The anti-reflection member may reduce a reflectance for external light. In some example embodiments, the anti-reflection member may be directly disposed on the input sensing unit ISU through a continuous process.

The anti-reflection member may include a light-shielding pattern overlapping a reflective structure that is disposed under the anti-reflection member. The anti-reflection member may alternatively or additionally include a color filter. The color filter may be disposed between the light-shielding patterns, and may include a first-color color filter, a second-color color filter, and a third-color color filter respectively corresponding to a first color pixel, a second color pixel and a third color pixel.

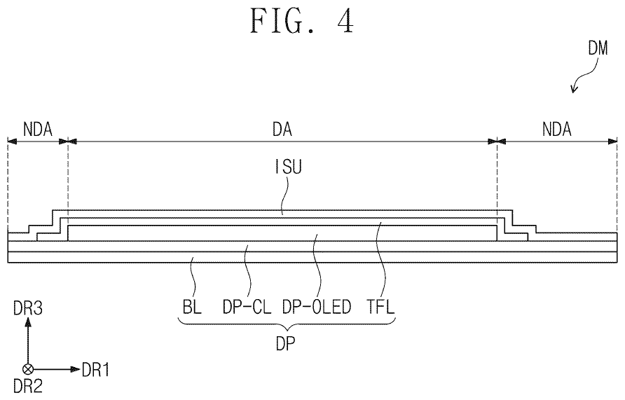

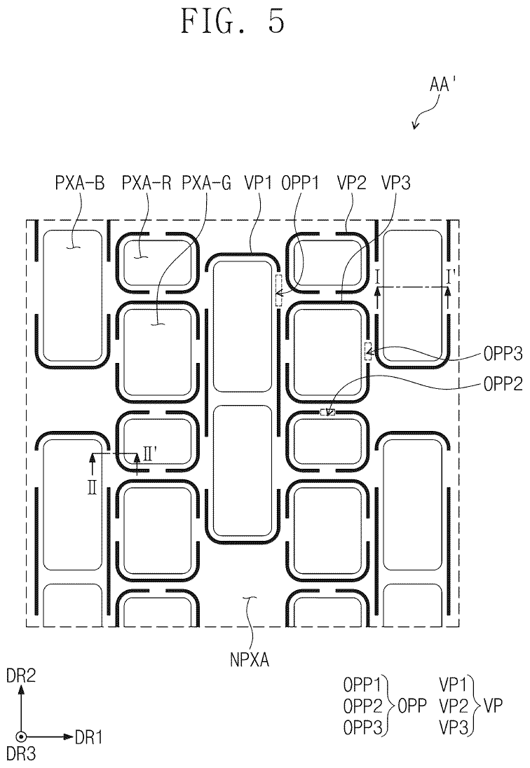

FIG. 5 is an enlarged plan view of a portion of a display panel according to some example embodiments. FIG. 5 illustrates an enlarged view of an arrangement of a plurality of pixels and a valley pattern that is defined adjacent thereto, in the region AA′ illustrated in FIG. 1B.

Referring to FIG. 5, in the display panel DP (see FIG. 4) according to some example embodiments, a display region DA may include a plurality of pixel regions PXA-B, PXA-R, and PXA-G and a non-pixel region NPXA surrounding the plurality of pixel regions PXA-B, PXA-R, and PXA-G. The plurality of pixel regions PXA-B, PXA-R, and PXA-G may include a first pixel region PXA-B, a second pixel region PXA-R, and a third pixel region PXA-G. The first pixel region PXA-B, the second pixel region PXA-R, and the third pixel region PXA-G may each display light with different wavelengths. The first pixel region PXA-B may display first light, which may be light of a blue wavelength, the second pixel region PXA-R may display second light, which may be light of a red wavelength, and the third pixel region PXA-G may display third light, which may be light of a green wavelength.

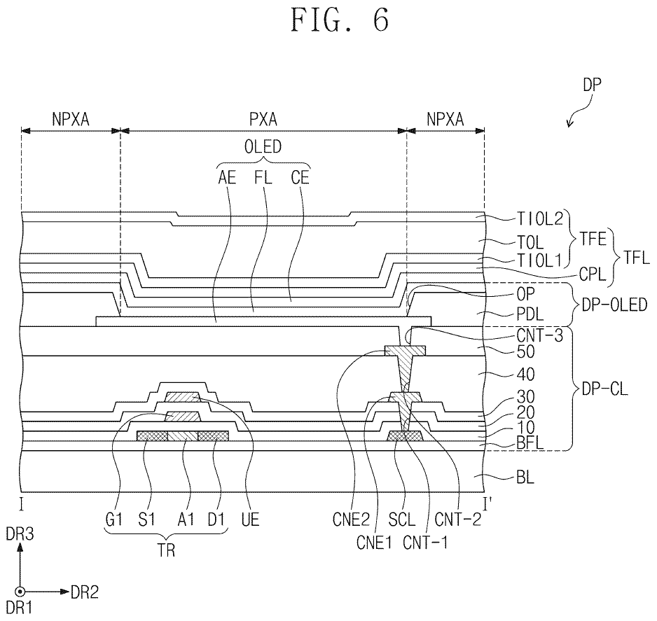

Meanwhile, the plurality of pixel regions PXA-B, PXA-R, and PXA-G may each be a region divided by the aforementioned pixel-defining film PDL (see FIG. 6). The non-pixel region NPXA may be or may correspond to a region between the adjacent pixel regions PXA-B, PXA-R, and PXA-G, and may be a region corresponding to the pixel-defining film PDL (see FIG. 6). Meanwhile, as used herein, the plurality of pixel regions PXA-B, PXA-R, and PXA-G may each correspond to the “pixel”. The plurality of pixel regions PXA-B, PXA-R, and PXA-G may be divided so as to correspond to a pixel opening OP (see FIG. 6) defined in the pixel-defining film PDL (see FIG. 6).

As illustrated in FIG. 5, the first pixel region PXA-B may constitute a first pixel group arranged along a second direction DR2, and the second pixel region PXA-R and the third pixel region PXA-G may constitute a second pixel group alternately arranged along the second direction DR2. The first pixel group composed of the first pixel region PXA-B and the second pixel group composed of the second pixel region PXA-R and the third pixel region PXA-G may be spaced apart from each other along a first direction DR1. Each of the first pixel group and the second pixel group may be alternately arranged along the first direction DR1.

The plurality of pixel regions PXA-B, PXA-R, and PXA-G may have different areas depending on the wavelength of the emitted light. For instance, as illustrated in FIG. 5, the first pixel region PXA-B which emits the first light may have the greatest area, the second pixel region PXA-R which emits the second light may have the smallest area. However, some example embodiments are not limited thereto, and the pixel regions PXA-B, PXA-R, and PXA-G may have the same area, or the pixel regions PXA-B, PXA-R, and PXA-G may be defined to have an area ratio different from the ratio illustrated in FIG. 6. The plurality of pixel regions PXA-B, PXA-R, and PXA-G may also emit light with different colors other than the light of the blue wavelength, the light of the red wavelength, and the light of the green wavelength which are mentioned above.

The plurality of pixel regions PXA-B, PXA-R, and PXA-G may each have a rectangular shape, and in some cases may include rounded and/or beveled and/or chamfered corners on a plane. In some example embodiments, the first pixel region PXA-B and the third pixel region PXA-G may each have a rectangular shape with rounded corners which has long sides extending in the second direction DR2 and short sides extending in the first direction DR1. In some example embodiments, the second pixel region PXA-R may have a rectangular shape with rounded corners which has long sides extending in the first direction DR1 and short sides extending in the second direction DR2. However, the shapes of the plurality of pixel regions PXA-B, PXA-R, and PXA-G are not limited thereto.

In each of the plurality of pixel regions PXA-B, PXA-R, and PXA-G, a valley pattern VP overlapping the non-pixel region NPXA and surrounding a portion of each of the plurality of pixel regions PXA-B, PXA-R, and PXA-G is defined. The valley pattern VP may surround a portion of each of the plurality of pixel regions PXA-B, PXA-R, and PXA-G, and may not surround the remaining portion. As used herein, a portion, of the valley pattern VP, which does not surround the plurality of pixel regions PXA-B, PXA-R, and PXA-G is defined and described as an open portion OPP. A proportion of the open portion OPP in each of the valley patterns VP may be about 10% to about 50%. When the proportion of the open portion OPP in each of the valley patterns VP is less than about 10%, a driving voltage may rise excessively, thereby reducing the efficiency of the display panel. When the proportion of the open portion OPP in each of the valley patterns VP is more than about 50%, a lateral leakage current and/or color mixture may be generated excessively, or the like may occur between the adjacent pixels, and thus an optical property of the display panel may be degraded. The open portions OPP defined in each of the valley patterns VP may each be defined not to face each other. When the open portions OPP are defined to face each other, a lateral leakage current may occur between the adjacent pixels where the open portions OPP facing each other are defined. However, in some example embodiments, since the open portions OPP are defined not to face each other, it is possible to prevent or reduce the likelihood of and/or impact form a current flowing in a direction of a plane defined by the first direction DR1 and the second direction DR2 other than a target direction.

The valley pattern VP may include a first valley pattern VP1 surrounding a portion of the first pixel region PXA-B, a second valley pattern VP2 surrounding the second pixel region PXA-R, and a third valley pattern VP3 surrounding the third pixel region PXA-G. A first open portion OPP1 which does not surround a portion of the first pixel region PXA-B may be defined in the first valley pattern VP1, a second open portion OPP2 which does not surround a portion of the second pixel region PXA-R may be defined in the second valley pattern VP2, and a third open portion OPP3 which does not surround a portion of the third pixel region PXA-G may be defined in the third valley pattern VP3.

However, some example embodiments are not limited thereto, and if necessary or desirable, the valley patterns VP1, VP2, and VP3 may have a shape entirely surrounding each of the plurality of pixel regions PXA-B, PXA-R, and PXA-G, and the open portions OPP1, OPP2, and OPP3 may not be defined in the valley patterns VP1, VP2, and VP3.

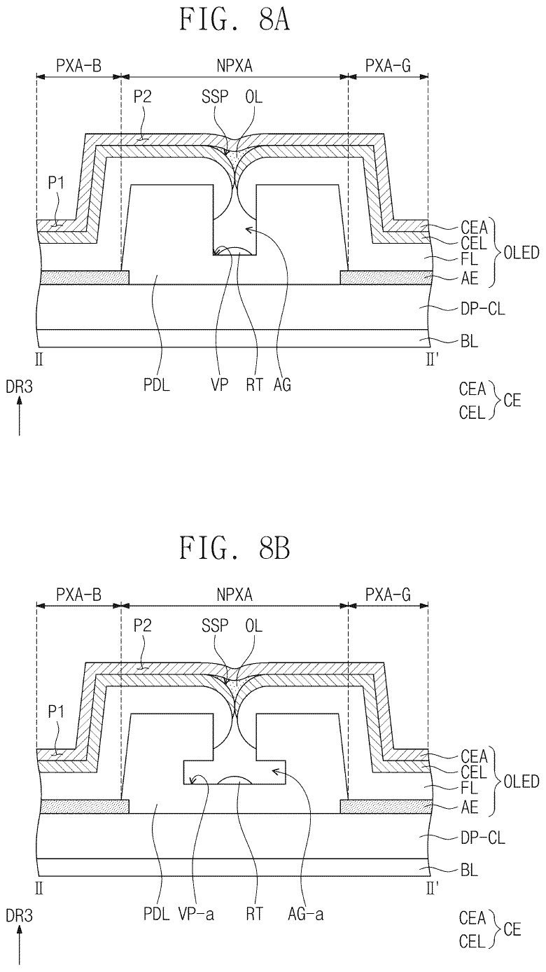

The valley pattern VP is defined in the pixel-defining film PDL (see FIG. 6). On a cross-section, the valley pattern VP may have a shape depressed along a thickness direction of the pixel-defining film PDL (see FIG. 6) on an upper surface of the pixel-defining film PDL (see FIG. 6). A cross-sectional shape of the valley pattern VP will be described in detail with reference to FIG. 8A and below.

In the display panel according to some example embodiments, the valley patterns VP1, VP2, and VP3 surrounding a portion of each of the pixel regions are defined so as to prevent or reduce the likelihood of and/or impact from a lateral leakage current from occurring between the adjacent pixels. Meanwhile, as used herein, the wording the “lateral leakage current” means a current flowing in another direction crossing a third direction DR3, other than a current flowing in the third direction DR3, which is the direction where light-emitting elements are stacked, for example, a direction where an image is displayed. On a plane defined by the first direction DR1 and the second direction DR2, the lateral leakage current may mean the current flowing in a direction parallel to the plane. In the display panel according to some example embodiments, since the valley patterns VP1, VP2, and VP3 depressed in the thickness direction of the pixel-defining film are defined, color mixture between the adjacent pixel regions may be prevented or reduced in likelihood of occurrence and/or in impact from occurrence, and luminance degradation may be prevented or reduced, by preventing or reducing the lateral leakage current from occurring.

FIG. 6 is a cross-sectional view of a portion of a display panel included in a display module according to some example embodiments. FIG. 6 illustrates a cross-section taken along line I-I′ of FIG. 5. Regarding one pixel included in the display panel according to some example embodiments, FIG. 6 illustrates a light-emitting element and a transistor which are included in the pixel.

Referring to FIG. 6, in a display panel DP according to some example embodiments, a circuit element layer DP-CL, a display element layer DP-OLED, and an upper insulation layer TFL may be sequentially disposed on a base layer BL.

The circuit element layer DP-CL includes at least one insulation layer and a circuit element. The circuit element includes a signal line, a driving circuit of a pixel, and the like. The circuit element layer DP-CL may be formed through a process where an insulation layer, a semiconductor layer, and a conductive layer are formed by coating, deposition, etching, etc., and through a process where an insulation layer, a semiconductor layer, and a conductive layer are patterned by a photolithography process.

A buffer layer BFL may include at least one of inorganic layers which are stacked. A semiconductor pattern is disposed on the buffer layer BFL. The buffer layer BFL may improve adhesion between the base layer BL and the semiconductor pattern.

The semiconductor pattern may include polysilicon. However, example embodiments are not limited thereto, and the semiconductor pattern may also include amorphous silicon and/or metal oxide. FIG. 6 only illustrates some of the semiconductor patterns, and semiconductor patterns may further be disposed in another region of the pixel on a plane. The semiconductor patterns may be arranged in accordance with a specific rule, e.g., a specific design rule, across pixels.

The semiconductor pattern has different electrical properties according to whether the semiconductor pattern is doped, e.g., doped with impurities, or not. The semiconductor pattern may include a first region A1 with low doping concentration and conductivity, and second regions S1 and D1 with relatively high doping concentration and conductivity. One second region S1 may be disposed at one side of the first region A1, and the other second region D1 may be disposed at the other side of the first region A1. The second regions S1 and D1 may be doped with an N-type dopant such as but not limited to phosphorus and/or arsenic, or a P-type dopant such as but not limited to boron. A P-type transistor includes a doped region that is doped with the P-type dopant. The first region A1 may be an undoped region, or may be doped at a lower concentration than the second regions S1 and D1, and in some cases may correspond to a channel region.

The second regions S1 and D1 substantially serve as an electrode or a signal line. The one second region S1 may correspond to a source of the transistor, and the other second region D1 may be a drain. FIG. 6 illustrates a portion of a connection signal line SCL formed from the semiconductor pattern. Although not illustrated separately, the connection signal line SCL may be connected to a drain of a transistor TR on a plane.

A first insulation layer 10 may be disposed on the buffer layer BFL. The first insulation layer 10 overlaps a plurality of pixels in common which are disposed in a display region DP-DA, and covers the semiconductor pattern. The first insulation layer 10 may be or may include an inorganic layer and/or an organic layer, and may have a single- or multi-layered structure. The first insulation layer 10 may include at least one among aluminum oxide, titanium oxide, silicon oxide, silicon oxynitride, zirconium oxide, and hafnium oxide. An insulation layer of the circuit element layer DP-CL to be described later as well as the first insulation layer 10 may be an inorganic layer and/or an organic layer, and may have a single- or multi-layered structure.

A gate G1 is disposed on the first insulation layer 10. The gate G1 may be a portion of a metal pattern. The gate G1 may overlap or at least partly overlap the first region A1. The gate G1 may function as a mask in a process of doping the semiconductor pattern; example embodiments, however, are not limited thereto.

A second insulation layer 20 may be disposed on the first insulation layer 10, and may cover the gate G1. The second insulation layer 20 overlaps the pixels in common. An upper electrode UE may be disposed on the second insulation layer 20. The upper electrode UE may overlap the gate G1. The upper electrode UE may include multiple metal layers. The upper electrode UE may be omitted in some example embodiments.

A third insulation layer 30 may be disposed on the second insulation layer 20, and may cover the upper electrode UE. A first connection electrode CNE1 may be disposed on the third insulation layer 30. The first connection electrode CNE1 may be connected to the connection signal line SCL through a contact hole CNT-1 which passes through the first to third insulation layers 10 to 30.

A thickness of and/or a material composition of each of the first through third insulating layers 10 to 30 may be the same; alternatively at least one of the first through third insulating layers 10 to 30 may be different from others of the first through third insulating layers 10 to 30.

A fourth insulation layer 40 may be disposed on the third insulation layer 30, and a fifth insulation layer 50 may be disposed on the fourth insulation layer 40. The fifth insulation layer 50 may be an organic layer. A second connection electrode CNE2 may be disposed on the fifth insulation layer 50. The second connection electrode CNE2 may be connected to the first connection electrode CNE1 through a contact hole CNT-2 which passes through the fourth insulation layer 40 and the fifth insulation layer 50. A sixth insulation layer 60 may be disposed on the fifth insulation layer 50, and may cover the second connection electrode CNE2. The sixth insulation layer 60 may be an organic layer.

According to some example embodiments, a first portion P10 and a third portion P30 of signal lines SGL described with reference to FIG. 3 may be disposed at a same layer as the gate G1, and a second portion P20 may be disposed at a same layer as the second connection electrode CNE2. Bridge wires TL-B described with reference to FIG. 3 may be disposed at a same layer as the second connection electrode CNE2.

A light-emitting element OLED may be disposed on the sixth insulation layer 60. A first electrode AE may be disposed on the sixth insulation layer 60. The first electrode AE is connected to the second connection electrode CNE2 through a contact hole CNT-3 which passes through the sixth insulation layer 60. The first electrode AE may be or may correspond to an anode; example embodiments are not limited thereto. Since a pixel opening OP is defined in a pixel-defining film PDL, the pixel-defining film PDL exposes at least a portion of the first electrode AE. The pixel-defining film PDL may be or may include an organic layer.

As illustrated in FIGS. 5 and 6, the display region DP-DA may include a pixel region PXA and a non-pixel region NPXA adjacent to the pixel region PXA. The non-pixel region NPXA may surround the pixel region PXA. In some example embodiments, the pixel region PXA is defined to correspond to a partial region of the first electrode AE that is exposed by the pixel opening OP.

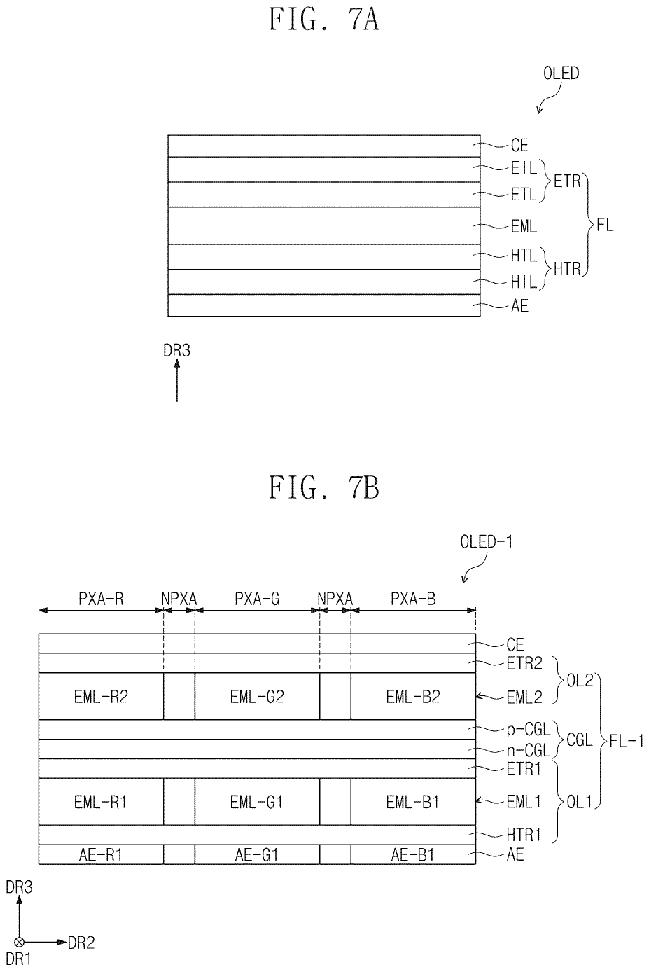

Referring, for example, to FIGS. 7A and 7B, a functional layer FL may be disposed inside the pixel opening OP. The functional layer FL may be disposed in the pixel region PXA and the non-pixel region NPXA in common. Alternatively, unlike what is illustrated, the functional layer FL may be patterned through a mask and formed separately in each of the pixels. The functional layer FL will be described in detail later with reference to FIG. 7A and below.

The upper insulation layer TFL may be disposed on the display element layer DP-OLED, and may include a plurality of thin films. According to some example embodiments, the upper insulation layer TFL may include a capping layer CPL and an encapsulation layer TFE disposed on the capping layer CPL. The capping layer CPL is disposed on a second electrode CE and is in contact with the second electrode CE. The second electrode may be or correspond to a cathode; example embodiments are not limited thereto. The capping layer CPL may include an organic material.

The encapsulation layer TFE may include a first inorganic encapsulation layer TIOL1, an organic encapsulation layer TOL disposed on the first inorganic encapsulation layer TIOL1, and a second inorganic encapsulation layer TIOL2 disposed on the organic encapsulation layer TOL. The first inorganic encapsulation layer TIOL1 and the second inorganic encapsulation layer TIOL2 protect or at least partially protect the display element layer DP-OLED from moisture/oxygen, and the organic encapsulation layer TOL protects or at least partially protects the display element layer DP-OLED from foreign matters such as dust particles. Thickness of and/or material compositions of the first inorganic encapsulation layer TIOL2 and the second inorganic encapsulation layer TIOL2 may be the same, or, alternatively, may be different; example embodiments are not limited thereto.

FIGS. 7A and 7B are each a cross-sectional view of a light-emitting element according to some example embodiments. The light-emitting element OLED in FIG. 6 may have a configuration of an embodiment of a light-emitting element illustrated in FIG. 7A or FIG. 7B.

Referring to FIG. 7A, a light-emitting element OLED according to an embodiment may include a first electrode AE, a functional layer FL, and a second electrode CE, and the functional layer FL may include a hole transport region HTR, a light-emitting layer EML, and an electron transport region ETR. The light-emitting element OLED according to some example embodiments may include a single light-emitting structure which is a stacked structure of the hole transport region HTR, the light-emitting layer EML, and the electron transport region ETR. For example, the functional layers FL illustrated in FIG. 6 may each include a single light-emitting structure which is a stacked structure of the hole transport region HTR, the light-emitting layer EML, and the electron transport region ETR.

In the light-emitting element OLED, the first electrode AE may be or may include a transmissive electrode, a semi-transmissive electrode, or a reflective electrode. The first electrode AE may be formed of a metal material, a metal alloy, or a conductive compound. The first electrode AE may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

When the first electrode AE is or includes the transmissive electrode, the first electrode AE may include a transparent metal oxide, for example, indium tin oxide (ITO), indium zinc oxide (IZO), zinc oxide (ZnO), indium tin zinc oxide (ITZO), etc. When the first electrode AE is or includes the semi-transmissive electrode or the reflective electrode, the first electrode AE may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, or a compound or mixture thereof (for example, a mixture of Ag and Mg). Alternatively, the first electrode AE may have a multi-layered structure including a reflective film or semi-transmissive film formed from the above materials, and a transparent conductive film formed from indium tin oxide (ITO), indium zinc oxide (IZO), zinc oxide (ZnO), indium tin zinc oxide (ITZO), etc. For instance, the first electrode AE may have a three-layer structure of ITO/Ag/ITO, but is not limited thereto. In addition, some example embodiments are not limited thereto, and the first electrode AE may include the aforementioned metal material, a combination of two or more metal materials selected from the aforementioned metal materials, an oxide of the aforementioned metal materials, or the like.

The second electrode CE may be or may include a transmissive electrode, a semi-transmissive electrode, or a reflective electrode. When the second electrode CE is the transmissive electrode, the second electrode CE may be composed of a transparent metal oxide, for example, indium tin oxide (ITO), indium zinc oxide (IZO), zinc oxide (ZnO), indium tin zinc oxide (ITZO), etc.

When the second electrode CE is or includes the semi-transmissive electrode or the reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W or a compound or mixture containing the above materials (for example, AgMg, AgYb, or MgYb). Alternatively, the second electrode CE may have a multi-layered structure including a reflective film or semi-transmissive film formed from the above materials, and a transparent conductive film formed from indium tin oxide (ITO), indium zinc oxide (IZO), zinc oxide (ZnO), indium tin zinc oxide (ITZO), etc. For instance, the second electrode CE may include the aforementioned metal material, a combination of two or more metal materials selected from the aforementioned metal materials, an oxide of the aforementioned metal materials, or the like. The multi-layered structure of the second electrode CE will be described in detail later with reference to FIG. 8A and below.

The light-emitting layer EML may be or may include a layer including a light-emitting material. The light-emitting layer EML may have a multi-layered structure having a single layer composed of a single material, a single layer composed of a plurality of different materials, or multiple layers composed of a plurality of different materials. The light-emitting layer may include a fluorescent or phosphorescent material. In the light-emitting element OLED according to some example embodiments, the light-emitting layer EML may include one or more of an organic light-emitting material, an organometallic complex, quantum dots, or the like as a light-emitting material.

FIG. 7A illustrates that the light-emitting element OLED includes one (e.g., only one) light-emitting layer EML, but the light-emitting element OLED may further include an auxiliary light-emitting layer which increases luminous efficiency in addition to a main light-emitting layer which includes a light-emitting material emitting a predetermined color. In addition, in an embodiment, the light-emitting layer EML may also have a stacked structure of a plurality of sub-light emitting layers with configurations of different light-emitting materials.

The light-emitting element OLED may include the hole transport region HTR disposed between the first electrode AE and the light-emitting layer EML. The hole transport region HTR may include at least one among a hole injection layer HIL, a hole transport layer HTL, a light-emitting auxiliary layer, and an electron blocking layer. For instance, the hole transport region HTR may include the hole injection layer HIL and the hole transport layer HTL which are sequentially stacked on the first electrode AE.

The light-emitting element OLED may include the electron transport region ETR disposed between the light-emitting layer EML and the second electrode CE. The electron transport region ETR may include at least one among a hole blocking layer, an electron transport layer ETL, and an electron injection layer EIL. For instance, the electron transport region ETR may include the electron transport layer ETL and the electron injection layer EIL which are disposed on the light-emitting layer EML, but some example embodiments are not limited thereto. The electron transport region ETR may have a multi-layered structure having a single layer composed of a single material, a single layer composed of a plurality of different materials, or multiple layers composed of a plurality of different materials.

Referring to FIG. 7B, a light-emitting element OLED-1 according to some example embodiments may include a first electrode AE, a functional layer FL-1, and a second electrode CE, and the functional layer FL-1 may include a plurality of emissive stacks OL1 and OL2. The plurality of emissive stacks OL1 and OL2 may respectively include light-emitting layers EML1 and EML2. Accordingly, the functional layer FL-1 may include the plurality of light-emitting layers EML1 and EML2. For example, the light-emitting element OLED-1 according to some example embodiments may be or may include a light-emitting element with a tandem structure including the plurality of light-emitting layers EML1 and EML2 that are separated from each other.

The light-emitting element OLED-1 according to some example embodiments may further include a charge generation layer CGL. When a voltage is applied to the light-emitting element OLED-1, the charge generation layer CGL may generate charges (electrons and holes) by forming a complex through an oxidation-reduction reaction. The charge generation layer CGL may provide the generated charges to each of the adjacent emissive stacks OL1 and OL2. The charge generation layer CGL may increase the efficiency of current generated in each of the adjacent emissive stacks OL1 and OL2, and may serve to adjust the balance of charges between the adjacent emissive stacks OL1 and OL2.

The charge generation layer CGL may have a layer structure in which an N-type charge generation layer n-CGL and a P-type charge generation layer p-CGL are joined to each other or form a junction therebetween.

The N-type charge generation layer n-CGL may be or may include a charge generation layer for providing electrons to the adjacent emissive stacks OL1 and OL2. The N-type charge generation layer n-CGL may be or may include a layer in which a base material is doped with an N-dopant. The P-type charge generation layer p-CGL may be or may include a charge generation layer for providing holes to the adjacent emissive stacks OL1 and OL2. The P-type charge generation layer p-CGL may be or may include a layer in which a base material is doped with a P-dopant.

The light-emitting element OLED-1 may include a first emissive stack OL1 and a second emissive stack OL2 disposed on the first emissive stack OL1. The charge generation layer CGL may be disposed between the first emissive stack OL1 and the second emissive stack OL2.

The first emissive stack OL1 may include a first hole transport region HTR1, a first light-emitting layer EML1, and a first electron transport region ETR1, and the second emissive stack OL2 may include a second hole transport region HTR2, a second light-emitting layer EML2, and a second electron transport region ETR2.

The description of the hole transport region HTR described with reference to FIG. 7A may be equally applied to the first hole transport region HTR1 and the second hole transport region HTR2. In addition, in the light-emitting element OLED-1 according to some example embodiments, the first hole transport region HTR1 and the second hole transport region HTR2 may be formed with the same structure and formed from the same material. However, example embodiments are not limited thereto, and the first hole transport region HTR1 and the second hole transport region HTR2 may have different stacked structures, or the first hole transport region HTR1 and the second hole transport region HTR2 may be formed by including different hole transport materials.

The description of the light-emitting layer EML described with reference to FIG. 7A may be equally applied to the first light-emitting layer EML1 and the second light-emitting layer EML2. In addition, in the light-emitting element OLED-1 according to some example embodiments, the first light-emitting layer EML1 and the second light-emitting layer EML2 may be formed with the same structure and/or formed from the same material. However, example embodiments are not limited thereto, and the first light-emitting layer EML1 and the second light-emitting layer EML2 may have different stacked structures, or the first light-emitting layer EML1 and the second light-emitting layer EML2 may be formed by including different light-emitting materials. In addition, each of the first light-emitting layer EML1 and the second light-emitting layer EML2 may also include a plurality of sub-light emitting layers which are stacked, or auxiliary light-emitting layers.

The first light-emitting layer EML1 and the second light-emitting layer EML2 may each be patterned inside the opening OH (see FIG. 6) defined in the pixel-defining film PDL (see FIG. 6). The first light-emitting layer EML1 may include a first blue-light emitting layer EML-B1 overlapping a first pixel region PXA-B, a first red-light emitting layer EML-R1 overlapping a second pixel region PXA-R, and a first green-light emitting layer EML-G1 overlapping a third pixel region PXA-G. The second light-emitting layer EML2 may include a second blue-light emitting layer EML-B2 overlapping the first pixel region PXA-B, a second red-light emitting layer EML-R2 overlapping the second pixel region PXA-R, and a second green-light emitting layer EML-G2 overlapping the third pixel region PXA-G. However, example embodiments are not limited thereto, and if necessary, each of the first light-emitting layer EML1 and the second light-emitting layer EML2 may also substantially constitute one component by being provided throughout the first to third pixel regions PXA-B, PXA-R, and PXA-G and a non-pixel region NPXA in common.

The description of the electron transport region ETR described with reference to FIG. 7A may be equally applied to the first electron transport region ETR1 and the second electron transport region ETR2. In addition, in the light-emitting element OLED-1 according to some example embodiments, the first electron transport region ETR1 and the second electron transport region ETR2 may be formed with the same structure and formed from the same material. However, example embodiments are not limited thereto, and the first electron transport region ETR1 and the second electron transport region ETR2 may have different stacked structures, or the first electron transport region ETR1 and the second electron transport region ETR2 may be formed by including different electron transport materials.

However, FIG. 7B illustrates that each of the first hole transport region HTR1, the second hole transport region HTR2, the first electron transport region ETR1, and the second electron transport region ETR2 may substantially constitute or correspond to one component by being provided throughout the first to third pixel regions PXA-B, PXA-R, and PXA-G and the non-pixel region NPXA in common, but example embodiments are not limited thereto, and if necessary or desirable, a part or all of the first hole transport region HTR1, the second hole transport region HTR2, the first electron transport region ETR1, and the second electron transport region ETR2 may be patterned inside the opening OP (see FIG. 6) defined in the pixel-defining film PDL (see FIG. 6).

FIG. 8A is an enlarged cross-sectional view of a portion of a display panel according to some example embodiments. FIG. 8B is an enlarged cross-sectional view of a portion of a display panel according to some example embodiments. FIG. 8A illustrates a cross-section taken along line II-II′ of FIG. 5. FIG. 8B illustrates a cross section of some example embodiments on the basis of the cross section illustrated in FIG. 8A. Hereinafter, in explaining a display panel according to some example embodiments with refence to FIGS. 8A and 8B, the components previously described with reference to FIGS. 4 to 7B will be denoted as same reference numerals or symbols and the detailed description thereof will be omitted.

Referring to FIG. 8A, a display panel according to some example embodiments includes a base layer BL, a circuit element layer DP-CL disposed on the base layer BL, and a pixel-defining film PDL and a light-emitting element OLED which are disposed on the circuit element layer DP-CL.

The light-emitting element OLED may include a first electrode AE, a functional layer FL, and a second electrode CE which are sequentially stacked. The first electrode AE may correspond to pixel regions PXA-B and PXA-G, and may be disposed on the circuit element layer DP-CL. The functional layer FL and the second electrode CE may overlap the pixel regions PXA-B and PXA-G and a non-pixel region NPXA, and may be disposed on the first electrode AE or the pixel-defining film PDL. A portion, of each of the functional layer FL and the second electrode CE, overlapping the pixel regions PXA-B and PXA-G may be disposed on the first electrode AE, and a portion, of each of the functional layer FL and the second electrode CE, overlapping the non-pixel region NPXA may be disposed on the pixel-defining film PDL.

The pixel-defining film PDL may correspond to the non-pixel region NPXA, and may be disposed on the circuit element layer DP-CL. A valley pattern VP is defined in the pixel-defining film PDL. The valley pattern VP may have a shape depressed in a third direction DR3 which is a thickness direction from an upper surface of the pixel-defining film PDL. The valley pattern VP may have a shape depressed from the upper surface of the pixel-defining film PDL toward a lower surface of the pixel-defining film PDL. Meanwhile, a portion of the valley pattern VP where the open portion OPP (see FIG. 4) is formed may be a portion where the upper surface of the pixel-defining film PDL is not depressed and maintains a flat surface.

A portion of the light-emitting element OLED may be disposed inside the valley pattern VP. Since the valley pattern VP has the shape depressed from the upper surface of the pixel-defining film PDL, the light-emitting element OLED may cover only a portion of the entire surface of the valley pattern VP. The light-emitting element OLED may cover only a portion of the entire surface of the valley pattern VP, and may not cover the remaining portion. An air gap AG may be defined between the valley pattern VP and the light-emitting element OLED. At least a portion of the light-emitting element OLED may have a shape cut by the air gap AG in the non-pixel region NPXA. For instance, at least a portion of the charge generation layer CGL (see FIG. 7B) may have a shape cut by the air gap AG in the non-pixel region NPXA. At least a portion of the second electrode CE may be electrically disconnected by the air gap AG in the non-pixel region NPXA. In addition, a residual substance RT, which includes the same material as that included in the light-emitting element OLED, may be disposed on a lower surface of the valley pattern VP, according to a depression shape, depression depth, depression width, taper angle, and the like of the valley pattern VP.

A portion of the functional layer FL may be disposed on a side surface of the valley pattern VP. A thickness of the functional layer FL disposed on the side surface of the valley pattern VP may be relatively smaller than a thickness of the functional layer FL disposed on the upper surface of the pixel-defining film PDL. Accordingly, in the functional layer FL disposed on the side surface of the valley pattern VP, resistance may increase, and a leakage current in a direction to the valley pattern VP may be prevented. FIG. 8A illustrates that a portion of the functional layer FL of the light-emitting element OLED is disposed inside the valley pattern VP. However, some example embodiments are not limited thereto, and if necessary, both of the functional layer FL and the second electrode CE which are included in the light-emitting element OLED may be disposed inside the valley pattern VP.

A depression pattern SSP overlapping the non-pixel region NPXA and corresponding to the valley pattern VP is defined in the light-emitting element OLED. The depression pattern SSP may have a shape depressed toward the side surface of the valley pattern VP. The shape of the depression pattern SSP may be indirectly defined by the shape of the valley pattern VP.

The second electrode CE may have a multi-layered structure. The second electrode CE may include a first layer CEL, and a second layer CEA disposed on the first layer CEL. The depression pattern SSP may be defined on an upper surface of the first layer CEL. The depression pattern SSP may be defined as a portion, of the upper surface of the first layer CEL, which is depressed toward the valley pattern VP. Since the depression pattern SSP is defined, a stepped portion may be generated on the upper surface of the first layer CEL. A height from the base layer BL may be relatively low in a portion of the first layer CEL where the depression pattern SSP is defined, compared to a portion of the first layer CEL where the depression pattern SSP is not defined. Since the depression pattern SSP is defined, a portion of the first layer CEL may be electrically disconnected in the non-pixel region NPXA.

An organic layer OL may be disposed between the first layer CEL and the second layer CEA. The organic layer OL may be disposed between the depression pattern SSP and the second layer CEA. The organic layer OL may be spaced apart from the functional layer FL of the light-emitting element OLED. Accordingly, even when the organic layer OL is disposed, the organic layer OL may not affect an operation of the light-emitting element OLED, so that the light-emitting element OLED may be operated normally.

The organic layer OL fills at least a portion of the depression pattern SSP. The organic layer OL may fill the depression pattern SSP, and thus serve to compensate for the stepped portion caused by the depression pattern SSP. The second layer CEA directly disposed on the organic layer OL may have relatively greater upper-surface flatness and layer stability than the first layer CEL where the depression pattern SSP is defined.

The second layer CEA may be directly disposed on the organic layer OL. The second layer CEA may include a first portion P1 overlapping the pixel regions PXA-B and PXA-G, and a second portion P2 overlapping the non-pixel region NPXA. The first portion P1 of the second layer CEA may be directly disposed on the first layer CEL, and at least a portion of the second portion P2 of the second layer CEA may be directly disposed on the organic layer OL. Even when a portion of the first layer CEL in the second electrode CE is electrically disconnected in the non-pixel region NPXA, the second electrode CE may perform an electrical function by including the second layer CEA. The second portion P2 of the second layer CEA may be disposed on the organic layer OL, thereby having high continuity. Since the first portion P1 of the second layer CEA is in contact with the first layer CEL, the second electrode CE may have electrically stable continuity in the non-pixel region NPXA.

The first layer CEL may have a stacked structure of a (1-1)-th layer and a (1-2)-th layer which contain different materials (e.g., at least one different material). The first layer CEL have a multi-layered structure including a reflective film or semi-transmissive film formed from Ag, Mg, Cu, Al, Pt, Pd, Au, Ni, Nd, Ir, Cr, Li, Ca, LiF/Ca, LiF/Al, Mo, Ti, Yb, W, or a compound or mixture containing the above materials, and a transparent conductive film formed from indium tin oxide (ITO), indium zinc oxide (IZO), zinc oxide (ZnO), indium tin zinc oxide (ITZO), etc. The first layer CEL may have a stacked structure of the (1-1)-th layer containing Ag, and the (1-2)-th layer containing at least one among ITO, IZO, ZnO, and ITZO. The second layer CEA may include the same material as the material included in the (1-2)-th layer. The second layer CEA may be a transparent conductive film formed from ITO, IZO, ZnO, ITZO, etc.

The organic layer OL is composed of a first material. A glass transition temperature of the first material is about 50° C. to about 90° C. For instance, the glass transition temperature of the first material may be about 65° C. to about 90° C. The first material may be the same material as the material included in the functional layer FL of the light-emitting element OLED. For instance, the first material may be the same material as the material included in the hole transport region HTR (see FIG. 7A) or the electron transport region ETR (see FIG. 7A). The first material may include at least one among N,N′-di(naphthalene-1-yl)-N,N′-diphenyl-benzidine (NPB), N,N′-bis(3-methylphenyl)-N,N′-diphenyl-[1,1′-biphenyl]-4,4′-diamine (TPD), 1,3,5-Tri(m-pyridin-3-ylphenyl)benzene, 1,3,5-Tris(3-pyridyl-3-phenyl)benzene (TmPyPB), 2,2Ç (TPBi), 4,4′,4″-tris(N-carbazolyl)triphenylamine (TCTA), and 4,4′,4″-[tris(3-methylphenyl)phenylamino] triphenylamine (m-MTDATA). The first material may include any one of the compounds in Compound Group 1 below. However, the type of the first material is not limited thereto, and any material with a glass transition temperature of about 50° C. to about 90° C. may be applicable without limitation.

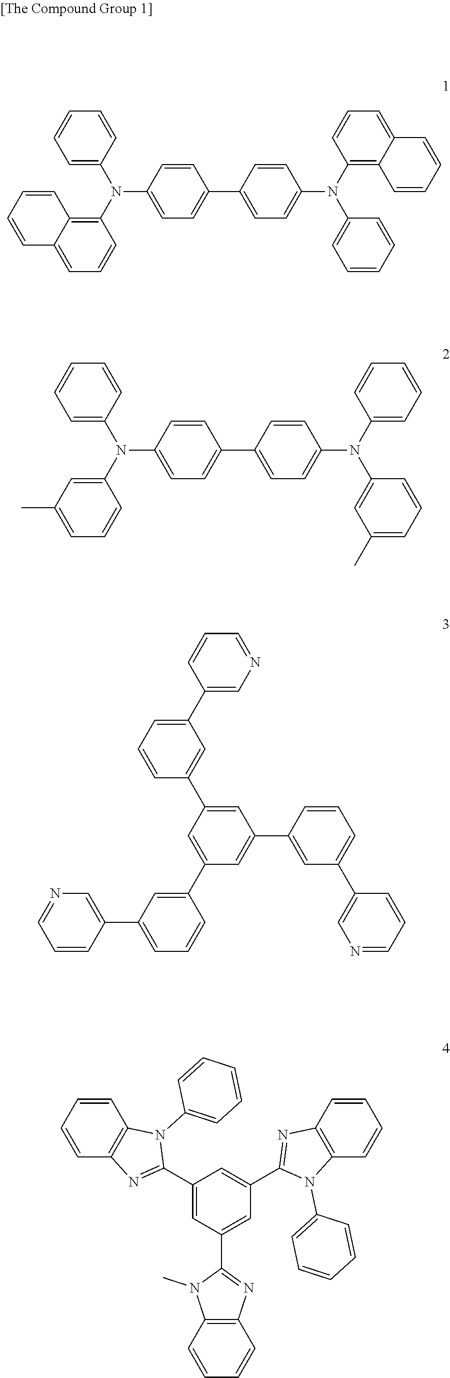 [SMILES: c1ccc(N(c2ccc(-c3ccc(N(c4ccccc4)c4cccc5ccccc45)cc3)cc2)c2cccc3ccccc23)cc1 ; Cc1cccc(N(c2ccccc2)c2ccc(-c3ccc(N(c4ccccc4)c4cccc(C)c4)cc3)cc2)c1 ; c1cncc(-c2cccc(-c3cc(-c4cccc(-c5cccnc5)c4)cc(-c4cccc(-c5cccnc5)c4)c3)c2)c1 ; Cn1c(-c2cc(-c3nc4ccccc4n3-c3ccccc3)cc(-c3nc4ccccc4n3-c3ccccc3)c2)nc2ccccc21]

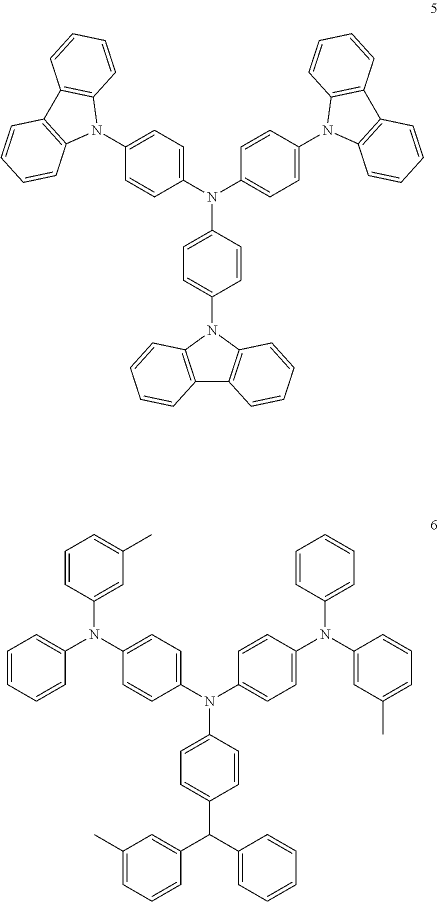 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; Cc1cccc(C(c2ccccc2)c2ccc(N(c3ccc(N(c4ccccc4)c4cccc(C)c4)cc3)c3ccc(N(c4ccccc4)c4cccc(C)c4)cc3)cc2)c1]

Referring to FIG. 8B, in a display panel according to some example embodiments, a valley pattern VP-a may be defined in a pixel-defining film PDL. The valley pattern VP-a may have a shape depressed in a direction from an upper surface of the pixel-defining film PDL to a lower surface of the pixel-defining film PDL. The valley pattern VP-a may include a first valley portion (not illustrated) depressed into a first width, and a second valley portion (not illustrated) extending in a thickness direction from the first valley portion and depressed into a second width that is greater than the first width. For example, the valley pattern VP-a illustrated in FIG. 8B may have a shape extending more in a direction of a plane defined by the first direction DR1 (see FIG. 1A) and the second direction DR2 (see FIG. 1A) at a certain depth than the valley pattern VP illustrated in FIG. 8A. Accordingly, a size of an air gap AG-a defined between the valley pattern VP-a and a light-emitting element OLED may be relatively great. As the width of the valley pattern VP-a varies along a third direction DR3 and the size of the air gap AG-a becomes greater, the functional layer FL, for example, the charge generation layer CGL (see FIG. 7B) may have a cut shape. Accordingly, a current flowing in a plane direction between adjacent pixels may be effectively prevented or reduced in likelihood of occurrence and/or in impact from occurrence.

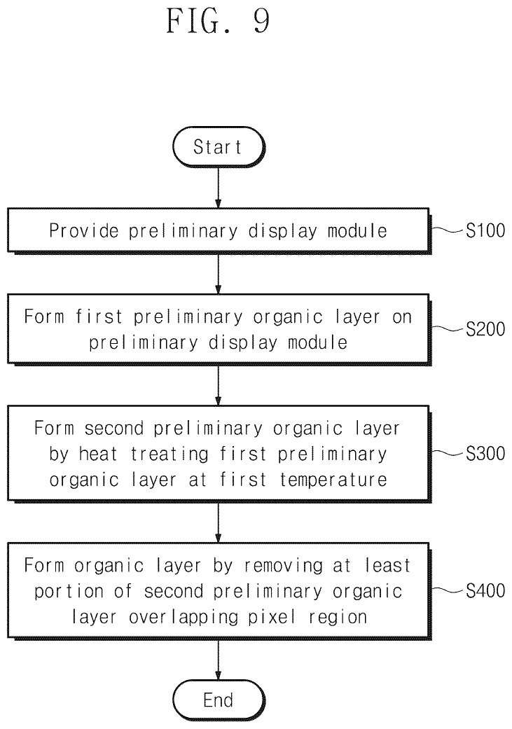

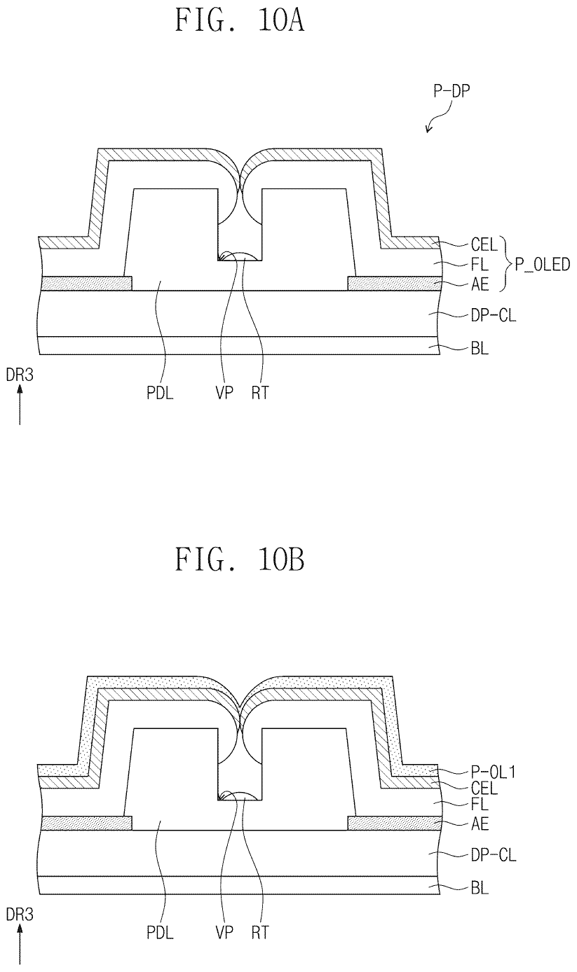

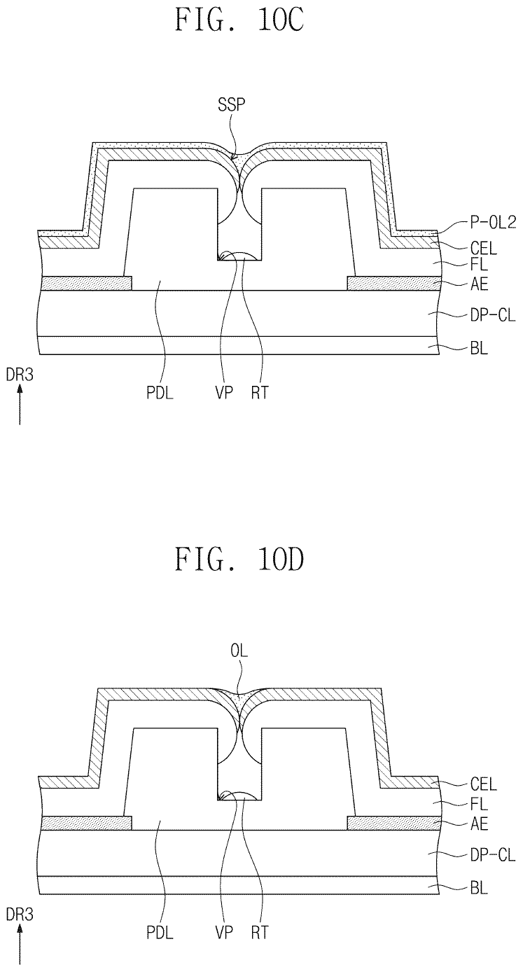

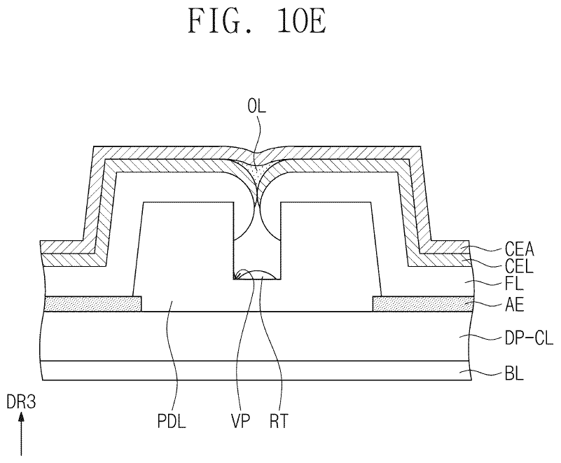

FIG. 9 is a flowchart illustrating a method of manufacturing a display panel according to some example embodiments. FIGS. 10A to 10E are cross-sectional views illustrating a part of steps of a method of manufacturing a display panel according to some example embodiments. FIGS. 10A to 10E each illustrate a corresponding cross section on the basis of the cross section illustrated in FIG. 8A.

A method of manufacturing a display panel according to some example embodiments may indicate a method of manufacturing a display panel DP according to some example embodiments described with reference to FIGS. 1 to 8B. In some example embodiments, a method of manufacturing a display panel including the light-emitting element OLED, which has been described with reference to FIGS. 1 to 8B, is provided. Hereinafter, in explaining a method of manufacturing a display panel according to an embodiment with reference to FIG. 9 and FIGS. 10A to 10E, components that are same as those described above will be denoted as same reference numerals or symbols and the detailed description thereof will be omitted.

Referring to FIG. 9, a method of manufacturing a display panel according to an embodiment includes an operation of providing a preliminary display module (S100), an operation of forming a first preliminary organic layer on the preliminary display module (S200), an operation of forming a second preliminary organic layer by heat treating the first preliminary organic layer at a first temperature (S300), and an operation of forming an organic layer by removing at least a portion of the second preliminary organic layer overlapping a pixel region (S400). Although not illustrated in FIG. 9, the method of manufacturing a display panel according to an embodiment may further include an operation of forming an auxiliary electrode layer on the organic layer to overlap the pixel region and a non-pixel region after the operation of forming the organic layer (S400).

Referring to FIG. 9 and FIGS. 10A to 10E, FIG. 10A schematically illustrates an operation of providing a preliminary display module P-DP (S100), FIG. 10B schematically illustrates an operation of forming a first preliminary organic layer P-OL1 on the preliminary display module P-DP (S200), FIG. 10C schematically illustrates an operation of forming a second preliminary organic layer P-OL2 by heat treating the first preliminary organic layer P-OL1 at a first temperature (S300), and FIG. 10D illustrates an operation of forming an organic layer OL by removing (e.g., etching such as wet etching) at least a portion of the second preliminary organic layer P-OL2 overlapping the a pixel region PXA (S400). FIG. 10E schematically illustrates an operation of forming an auxiliary electrode layer CEA on the organic layer OL after the operation of forming the organic layer OL (S400) illustrated in FIG. 10D.

Referring to FIG. 10A, the preliminary display module P-DP includes a pixel-defining film PDL and a plurality of preliminary light-emitting elements P-OLED. The aforementioned valley pattern VP is defined in the pixel-defining film PDL. The plurality of preliminary light-emitting elements P-OLED may include a first electrode AE, a functional layer FL, and a first layer CEL which are sequentially stacked.

Referring to FIGS. 10B and 10C, the first preliminary organic layer P-OL1 may be formed on the preliminary display module P-DP. The first preliminary organic layer P-OL1 may be formed on the first layer CEL.

The first preliminary organic layer P-OL1 may be formed by depositing a first material on an upper surface of the first layer CEL. As mentioned above, the first material may be a material that the organic layer OL (see FIG. 8A) is composed of. The first material may be an organic material with a glass transition temperature of about 50° C. to about 90° C. The first preliminary organic layer P-OL1 may be deposited in a setting at a lower temperature than the glass transition temperature of the first material. The first preliminary organic layer P-OL1 may be deposited in a setting at a lower temperature than the first temperature to be described later.

The second preliminary organic layer P-OL2 may be a result of heat treating the first preliminary organic layer P-OL1. The second preliminary organic layer P-OL2 may be formed by vacuum heat treating the first preliminary organic layer P-OL1 at the first temperature. The first material included in the first preliminary organic layer P-OL1 may be in a glassy state, and the first material included in the second preliminary organic layer P-OL2 may be in a rubbery state. The first preliminary organic layer P-OL1 in the glassy state may be heat treated at the first temperature, thereby forming the second preliminary organic layer P-OL2 in the rubbery state. Since the second preliminary organic layer P-OL2 is changed into the rubbery state, a degree to which the second preliminary organic layer P-OL2 fills a depression pattern SSP defined in the first layer CEL may be improved. The degree to which the second preliminary organic layer P-OL2 fills the depression pattern SSP may be greater than that of the first preliminary organic layer P-OL1.

The first temperature may be about 50° C. to about 90° C. For instance, the first temperature may be about 65° C. to about 90° C. When the first temperature is more than about 90° C., the functional layer FL disposed under the first preliminary organic layer P-OL1 may be thermally affected, which may result in a decrease in the function of the light-emitting element. Alternatively, when the first temperature is less than about 50° C., it may not be suitable for an amorphous polymer to become a rubbery state, and thus it may not be suitable for the organic layer OL (see FIG. 10E) to serve to compensate for a height deviation of the first layer CEL. The first temperature may be determined depending on the glass transition temperature of the first material. The first temperature may be substantially the same as the glass transition temperature of the first material, or may have an arbitrary value above the glass transition temperature of the first material.

Referring to FIGS. 10C and 10D, the organic layer OL may be formed by removing at least a portion of the second preliminary organic layer P-OL2 overlapping the pixel region PXA. The organic layer OL may be formed by removing a portion, of the second preliminary organic layer P-OL2, which does not fill the depression pattern SSP. The portion, of the second preliminary organic layer P-OL2, which does not fill the depression pattern SSP may be removed through an ashing process. For instance, of the operation of forming the organic layer OL may include a plasma ashing process, an ozone ashing process, or the like. However, of the operation of forming the organic layer OL is not limited thereto, and any process that exposes an upper surface of the first layer CEL may be adopted without limitation.

Referring to FIG. 10E, a second layer CEA may be formed on the organic layer OL and the first layer CEL. Meanwhile, as used herein, the second layer CEA may be referred to as an ‘auxiliary electrode layer’. The organic layer OL may fill the depression pattern SSP (see FIG. 10D) of the first layer CEL, and thus compensate for a height deviation of the first layer CEL. Accordingly, the second layer CEA may have high continuity throughout the pixel regions PXA-B and PXA-G (see FIG. 8A) and the non-pixel region NPXA, compared to the first layer CEL.

A display panel according to some example embodiments and/or an electronic apparatus including the same may include an organic layer composed of a first material, and thus the reliability may be improved by reducing occurrence of a lateral leakage current and simultaneously reducing contact resistance of an electrode within a light-emitting element. A display panel and an electronic apparatus including the same form a valley pattern, which has a depressed shape, inside a pixel-defining film so as to reduce the occurrence of the lateral leakage current. Since the valley pattern is formed, side effects such as electrical disconnection of the electrode or increased contact resistance of the electrode occur. On the contrary, in the display panel according to some example embodiments and the electronic apparatus including the same, the organic layer composed of the first material is disposed between components in the electrode, and thus element-driving reliability may be achieved by solving an issue of discontinuity of the electrode in virtue of secured flatness. Alternatively or additionally, since a glass transition temperature of the first material has a value below a certain numerical range, the element-driving reliability may be achieved such that movement of electrons and charges within the light-emitting element is performed normally by reducing thermal damage applied to the light-emitting element. Therefore, since the valley pattern is defined in the display panel according to some example embodiments and the electronic apparatus including the same, the occurrence of the lateral leakage current may be reduced, and simultaneously an issue of instability of the electrode and an issue of the thermal damage to the light-emitting element may be solved or improved upon, thereby improving the reliability of the apparatus.

In a display panel according to some example embodiments and an electronic apparatus including the same, a lateral leakage current between adjacent pixels may be reduced and color mixture between the pixels may be prevented, thereby improving display quality.

Since a display panel according to some example embodiments and an electronic apparatus including the same include an organic layer composed of a first material, the reliability may be improved by reducing occurrence of a lateral leakage current and simultaneously reducing contact resistance of an electrode within a light-emitting element.

According to a method of manufacturing a display panel according to some example embodiments, since an organic layer is formed at a first temperature, a display panel with element reliability maintained may be manufactured despite including an operation of heat treatment.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

In the above, descriptions have been made with reference to some example embodiments, but those skilled or of ordinary skill in the art may understand that various modifications and changes may be made to example embodiments insofar as such modifications and changes do not depart from the spirit and technical scope of the inventive concept set forth in the claims to be described later. Therefore, the technical scope of inventive concepts is not to be limited to the contents stated in the detailed description of the specification, but should be determined by the claims.

What is claimed is:

1. A display panel comprising:
a base layer in which a plurality of pixel regions and a non-pixel region surrounding the pixel regions are defined;
a pixel-defining film on the base layer, at least partly overlapping the non-pixel region, and in which a valley pattern depressed from an upper surface along a thickness direction is defined;
a plurality of light-emitting elements on the base layer, and in which a depression pattern corresponding to the valley pattern is defined; and
an organic layer including a first material and at least partly filling at least a portion of the depression pattern,
wherein a glass transition temperature of the first material is 50° C. to 90° C.

2. The display panel of claim 1, wherein the valley pattern at least partly surrounds at least a portion of each of the plurality of pixel regions.

3. The display panel of claim 1, wherein the first material comprises at least one of compounds in Compound Group 1 below:

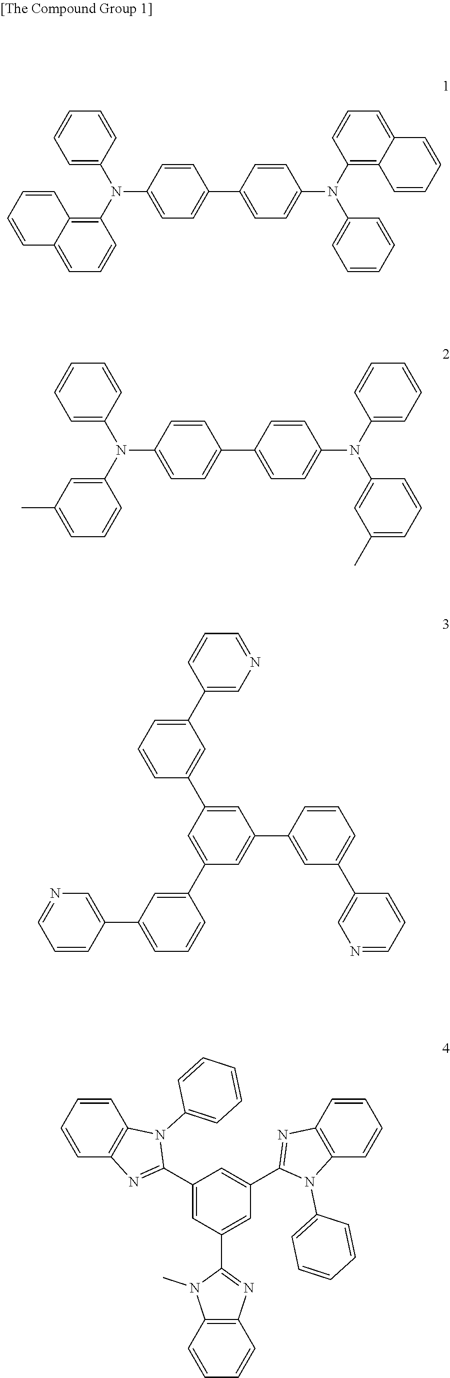 [SMILES: c1ccc(N(c2ccc(-c3ccc(N(c4ccccc4)c4cccc5ccccc45)cc3)cc2)c2cccc3ccccc23)cc1 ; Cc1cccc(N(c2ccccc2)c2ccc(-c3ccc(N(c4ccccc4)c4cccc(C)c4)cc3)cc2)c1 ; c1cncc(-c2cccc(-c3cc(-c4cccc(-c5cccnc5)c4)cc(-c4cccc(-c5cccnc5)c4)c3)c2)c1 ; Cn1c(-c2cc(-c3nc4ccccc4n3-c3ccccc3)cc(-c3nc4ccccc4n3-c3ccccc3)c2)nc2ccccc21]

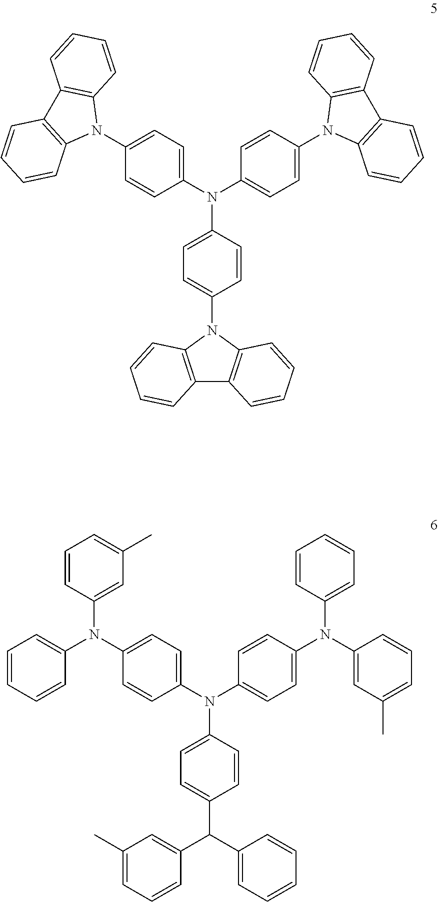 [SMILES: c1ccc2c(c1)c1ccccc1n2-c1ccc(N(c2ccc(-n3c4ccccc4c4ccccc43)cc2)c2ccc(-n3c4ccccc4c4ccccc43)cc2)cc1 ; Cc1cccc(C(c2ccccc2)c2ccc(N(c3ccc(N(c4ccccc4)c4cccc(C)c4)cc3)c3ccc(N(c4ccccc4)c4cccc(C)c4)cc3)cc2)c1]

4. The display panel of claim 1, wherein each of the plurality of light-emitting elements comprises:
a first electrode;
a functional layer on the first electrode; and
a second electrode on the functional layer,
wherein the pixel-defining film defines a pixel opening which exposes a portion of an upper surface of the first electrode and corresponds to each of the plurality of pixel regions.

5. The display panel of claim 4, wherein
the second electrode comprises a first layer on the functional layer, and a second layer on the first layer, and
the organic layer is between the first layer and the second layer.

6. The display panel of claim 5, wherein at least a portion of the first layer is electrically disconnected in the non-pixel region.

7. The display panel of claim 5, wherein the first layer comprises:
a (1-1)-th layer on the functional layer and containing silver (Ag); and
a (1-2)-th layer on the (1-1)-th layer, and containing at least one among indium tin oxide (ITO), indium zinc oxide (IZO), zinc oxide (ZnO), and indium tin zinc oxide (ITZO).

8. The display panel of claim 5, wherein the second layer comprises at least one among indium tin oxide (ITO), indium zinc oxide (IZO), zinc oxide (ZnO), and indium tin zinc oxide (ITZO).

9. The display panel of claim 5, wherein
the second layer comprises a first portion at least partially overlapping the plurality of pixel regions and a second portion at least partially overlapping the non-pixel region, and
the first portion is directly on the first layer.

10. The display panel of claim 9, wherein at least a portion of the second portion is directly on the organic layer.

11. The display panel of claim 4, wherein the functional layer comprises:
a hole transport region on the first electrode;
a light-emitting layer on the hole transport region; and
an electron transport region on the light-emitting layer.

12. The display panel of claim 11, wherein at least one of the hole transport region or the electron transport region comprises the first material.

13. The display panel of claim 4, wherein the functional layer comprises:
a first emissive stack including a first hole transport region, a first light-emitting layer on the first hole transport region, and a first electron transport region on the first light-emitting layer;
a charge generation layer on the first emissive stack; and
a second emissive stack including a second hole transport region, a second light-emitting layer on the second hole transport region, and a second electron transport region on the second light-emitting layer.

14. The display panel of claim 13, wherein at least a portion of the charge generation layer is a cut shape in the non-pixel region.

15. The display panel of claim 1, further comprising:
an encapsulation layer on the plurality of light-emitting elements and the pixel-defining film.

16. An electronic apparatus capable of providing an image, the electronic apparatus comprising:
a window;
a display panel under the window, and in which a plurality of pixel regions and a non-pixel region surrounding the pixel regions are defined; and
an external case coupled to the window and configured to accommodate the display panel,
wherein the display panel includes
a pixel-defining film at least partially overlapping the non-pixel region, and in which a pixel opening corresponding to each of the plurality of pixel regions and a valley pattern depressed from an upper surface along a thickness direction are defined,
a plurality of light-emitting elements of which at least a portion is in the pixel opening, and in which a depression pattern corresponding to the valley pattern is defined, and
an organic layer containing a first material and at least partially filling at least a portion of the depression pattern, wherein
a glass transition temperature of the first material is 50° C. to 90° C.

17. A method of manufacturing a display panel including a plurality of pixel regions and a non-pixel region surrounding the pixel regions, the method comprising:
providing a preliminary display module including a plurality of preliminary light-emitting elements and a pixel-defining film at least partially overlapping the non-pixel region and in which a valley pattern depressed along a thickness direction is defined;
forming a first preliminary organic layer on the preliminary display module;
forming a second preliminary organic layer by heat treating the first preliminary organic layer at a first temperature; and
forming an organic layer by removing, from an upper surface of the preliminary display module, at least a portion of the second preliminary organic layer overlapping the pixel regions,
wherein the first temperature is 50° C. to 90° C.

18. The method of claim 17, further comprising:
forming, on the organic layer and the preliminary display module, an auxiliary electrode layer to at least partially overlap the plurality of pixel regions and the non-pixel region after the forming of the organic layer.

19. The method of claim 17, wherein the organic layer includes a first material, and a glass transition temperature of the first material is equal to or greater than the first temperature.

20. The method of claim 17, wherein a material contained in the first preliminary organic layer is in a glassy state, and a material contained in the second preliminary organic layer is in a rubbery state.
